(19) United States
(12) Patent Application Publication
(10) Pub. No.: US 2009/0068586 A1
(43) Pub. Date: Mar. 12, 2009

(54) SILSESQUIOXANE RESIN, POSITIVE RESIST COMPOSITION, RESIST LAMINATE, AND METHOD OF FORMING RESIST PATTERN

(75) Inventors: Tsuyoshi Nakamura, Kawasaki-shi (JP); Koki Tamura, Kawasaki-shi (JP); Tomotaka Yamada, Kawasaki-shi (JP); Taku Hirayama, Kawasaki-shi (JP); Daisuke Kawana, Kawasaki-shi (JP); Takayuki Hosono, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: Tokyo Ohka Kogyo Co., Ltd., Kawasaki-shi (JP)

(21) Appl. No.: 12/247,876

(22) Filed: Oct. 8, 2008

Related U.S. Application Data
(62) Division of application No. 10/546,575, filed on May 23, 2006.

(30) Foreign Application Priority Data
Feb. 26, 2003 (JP) 2003-049679
Jul. 10, 2003 (JP) 2003-195179
Jul. 30, 2003 (JP) 2003-203721

(51) Int. Cl. G03F 7/004; G03F 7/20

(52) U.S. Cl. 430/270.1; 430/326

(57) ABSTRACT

A silsesquioxane resin, a positive resist composition, a resist laminate, and a method of forming a resist pattern that are capable of suppressing a degas phenomenon are provided, and a silicon-containing resist composition and a method of forming a resist pattern that are ideally suited to immersion lithography are also provided. The silsesquioxane resin includes structural units represented by the general shown below [wherein, R¹ and R² each represent, independently, a straight chain, branched, or cyclic saturated aliphatic hydrocarbon group; R³ represents an acid dissociable, dissolution inhibiting group containing a hydrocarbon group that includes an aliphatic monocyclic or polycyclic group; R⁴ represents a hydrogen atom, or a straight chain, branched, or cyclic alkyl group; X represents an alkyl group of 1 to 8 carbon atoms in which at least one hydrogen atom has been substituted with a fluorine atom; and m represents an integer from 1 to 3].

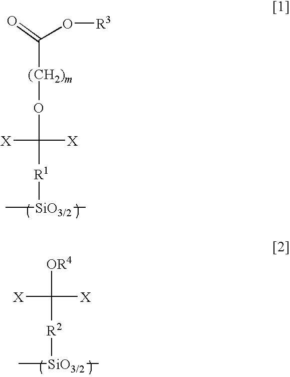

### RELATED APPLICATIONS

This application is a divisional of U.S. patent application Ser. No. 10/546,575, filed May 23, 2006, which is the U.S. National Phase under 35 U.S.C. §371 of PCT/JP2004/002173, filed Feb. 25, 2004, which was published in a language other than English, which claims priority under 35 U.S.C. § 119(a)-(d) to Japanese Patent Application No. 2003-203721, filed Jul. 30, 2003, Japanese Patent Application No. 2003-195179, filed Jul. 10, 2003, and Japanese Patent Application No. 2003-49679, filed Feb. 26, 2003. The contents of all of these applications are incorporated herein by reference in their entireties.

### TECHNICAL FIELD

The present invention relates to a silsesquioxane resin used in a positive resist composition or the like used during the formation of a resist pattern using high energy light or an electron beam, and also relates to a positive resist composition containing the silsesquioxane resin, a resist laminate in which the positive resist is used as the upper layer of two layers used in a two-layer resist process, a method of forming a resist pattern using the resist laminate, a positive resist composition used in a method of forming a resist pattern that includes an immersion lithography step, and a method of forming a resist pattern that includes an immersion lithography step that uses such a positive resist composition.

### BACKGROUND ART

In the production of semiconductor elements and liquid crystal display elements, a lithography step, in which a circuit pattern (resist pattern) is formed in a resist provided on top of a substrate, and an etching step, in which the formed resist pattern is used as a mask to partially etch and remove an insulating film or a conductive film formed as a base material on top of the substrate, are performed.

In recent years, advances in lithography techniques have lead to ongoing, rapid miniaturization of resist patterns. Recently, levels of resolution capable of forming line and space patterns of no more than 100 nm, and isolated patterns of no more than 70 nm n, are being demanded.

One typical technique for achieving miniaturization involves shortening of the wavelength of the exposure light source. Specifically, whereas conventionally ultraviolet radiation such as g-lines and i-lines have been used as the exposure light source, nowadays, mass production has already started using KrF excimer lasers (248 nm), and even ArF excimer lasers (193 nm) are now starting to be introduced. Furthermore, the use of even shorter wavelengths such as F₂ excimer lasers (157 nm), EUV (extreme ultraviolet), electron beams, X-rays, and soft X-rays are also being investigated.

One example of a known resist material that satisfies the high resolution requirements needed to enable reproduction of a pattern with very minute dimensions is a so-called positive chemically amplified resist composition, including a base resin that exhibits increased alkali solubility under the action of acid, and an acid generator that generates acid on exposure, dissolved in an organic solvent. Recently, chemically amplified resist compositions suited to short wavelength exposure light sources of no more than 200 nm have also been proposed (for example, see patent reference 1).

However, although chemically amplified resists exhibit high sensitivity and high resolution, they are not ideal for forming single-layer resist patterns with the type of high aspect ratio required to ensure favorable dry etching resistance, and if an attempt is made to form a resist pattern with an aspect ratio of 4 to 5, pattern collapse can become problematic.

On the other hand, a two-layer resist method using a chemically amplified resist has been proposed as one method that enables the formation of a resist pattern with high resolution and a high aspect ratio (for example, see patent references 2 and 3). In this method, first, an organic film is formed as the lower resist layer on top of a substrate, and an upper resist layer is then formed on top of the lower resist layer using a chemically amplified resist that includes a specific silicon-containing polymer. Subsequently, a resist pattern is formed in the upper resist layer using photolithography techniques, and by then using this resist pattern as a mask to conduct etching, thereby transferring the resist pattern to the lower resist layer, a resist pattern with a high aspect ratio is formed.

Furthermore, although the development of a silicon-containing resist composition that can be ideally applied to a method of forming a resist pattern that includes an immersion lithography step, as disclosed in the non-patent references 1 to 3, has been keenly sought, until now, no publications relating to such a composition have appeared.

[Patent Reference 1]

### Japanese Unexamined Patent Application, First Publication No. 2002-162745

[Patent Reference 2]

Japanese Unexamined Patent Application, First Publication No. Hei 6-202338

[Patent Reference 3]

Japanese Unexamined Patent Application, First Publication No. Hei 8-29987

[Non-Patent Reference 1]

### Journal of Vacuum Science & Technology B (U.S.), 1999, 17, No. 6, pp. 3306 to 3309

[Non-Patent Reference 2]

### Journal of Vacuum Science & Technology B (U.S.), 2001, 19, No. 6, pp. 2353 to 2356

[Non-Patent Reference 3]

### Proceedings of SPIE (U.S.), 2002, 4691, pp. 459 to 465

The chemically amplified resists used in the type of two-layer resist methods described above display no particular problems when used with comparatively long wavelength light source such as i-line radiation, but when a comparatively short wavelength high energy light with a wavelength of no more than 200 nm (such as an ArF excimer laser or the like) or an electron beam is used as the exposure light source, absorption is large, and transparency is poor, meaning forming a resist pattern at high resolution is difficult. Furthermore, another problem arises in that during exposure, organic gas is generated from the resist (degas), which can contaminate the exposure apparatus and the like. This organic gas can be broadly classified into two types: organic silicon-based gases generated by rupture of silicon-carbon bonds within the silicon-containing polymer, and organic non-silicon-based gases generated during either dissociation of the acid dissociable, dissolution inhibiting groups, or from the resist solvent. Both these types of gases can cause a deterioration in the transparency of the lenses within the exposure apparatus. Particularly in the case of the former gas type, once adhered to a lens, subsequent removal is extremely difficult, which can become a significant problem.

### DISCLOSURE OF INVENTION

Accordingly, an object of the present invention is to provide a silsesquioxane resin, a positive resist composition, a resist laminate, and a method of forming a resist pattern which provide a high level of transparency, and are able to prevent the type of degas phenomenon described above.

Furthermore, another object of the present invention is to provide a silicon-containing resist composition and a method of forming a resist pattern that are ideal for use with immersion lithography.

As a result of intensive investigations, the inventors of the present invention discovered that a silsesquioxane resin containing specific structural units, a positive resist composition containing the silsesquioxane resin as a base resin, a resist laminate containing the resist composition, a method of forming a resist pattern that uses the resist laminate, a positive resist composition containing a silsesquioxane resin, and a method of forming a resist pattern that uses the positive resist composition were able to achieve the objects described above, and they were thus able to complete the present invention.

In other words, a first aspect of the present invention for achieving the above objects is a silsesquioxane resin (hereafter also referred to as the “silsesquioxane resin (A1)”) containing structural units represented by general formulas [1] and [2] shown below:

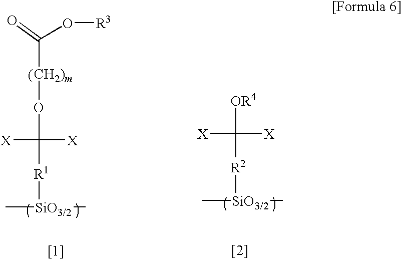

[wherein, R¹ and R² each represent, independently, a straight chain, branched, or cyclic saturated aliphatic hydrocarbon group, R³ represents an acid dissociable, dissolution inhibiting group that includes a hydrocarbon group containing an aliphatic monocyclic or polycyclic group, R⁴ represents a hydrogen atom, or a straight chain, branched, or cyclic alkyl group, each X group represents, independently, an alkyl group of 1 to 8 carbon atoms in which at least one hydrogen atom has been substituted with a fluorine atom, and m represents an integer from 1 to 3].

A second aspect of the present invention for achieving the above objects is a positive resist composition including a resin component (A) that exhibits increased alkali solubility under the action of acid, and an acid generator component (B) that generates acid on exposure, wherein the component (A) contains a silsesquioxane resin (A1) according to the first aspect.

A third aspect of the present invention for achieving the above objects is a resist laminate including a lower resist layer and an upper resist layer laminated on top of a support, wherein the lower resist layer is insoluble in alkali developing solution, but can by dry etched, and the upper resist layer is formed from a positive resist composition according to the second aspect.

A fourth aspect of the present invention for achieving the above objects is a method of forming a resist pattern, including the steps of selectively exposing a resist laminate according to the third aspect, conducting post exposure baking (PEB), conducting alkali developing to form a resist pattern (I) in the upper resist layer, and conducting dry etching using the resist pattern (I) as a mask, thereby forming a resist pattern (II) in the lower resist layer.

Furthermore, a fifth aspect of the present invention is a resist composition used in a method of forming a resist pattern that includes an immersion lithography step, wherein if the sensitivity when a 1:1 line and space resist pattern of 130 nm is formed by a normal exposure lithography process using a light source with a wavelength of 193 nm is termed X1, and the sensitivity when an identical 1:1 line and space resist pattern of 130 nm is formed by a simulated immersion lithography process, in which a step for bringing a solvent for the immersion lithography in contact with the resist film is inserted between the selective exposure step and the post exposure baking (PEB) step of a normal exposure lithography process, using a light source with a wavelength of 193 nm is termed X2, then the resist composition is a positive resist composition containing a silsesquioxane resin as the resin component for which the absolute value of [(X2/X1)−1]×100 is no more than 8.0.

Furthermore, a sixth aspect of the present invention is a method of forming a resist pattern that uses a positive resist composition according to the fifth aspect, wherein the method includes an immersion lithography step.

In terms of the fifth and sixth aspects of the present invention described above, the inventors of the present invention evaluated the suitability of resist films for use within a method of forming a resist pattern that includes an immersion lithography step using the analyses described below, and based on the results of these analyses, were able to evaluate individual resist compositions and the methods of forming a resist pattern that use those compositions.

In other words, in order to evaluate the resist pattern formation performance by immersion lithography, it was deemed adequate to analyze three factors: namely (i) the performance of the optical system using immersion lithography, (ii) the effect of the resist film on the immersion solvent, and (iii) degeneration of the resist film caused by the immersion solvent.

(i) Regarding the performance of the optical system, by envisaging the case where a photographic photosensitive plate with favorable surface water resistance is immersed in water, and a patterned light is then irradiated onto the surface of the plate, it is clear that in theory, provided no light transmission loss such as reflection or the like occurs at the water surface, or the interface between the water and the surface of the photosensitive plate, then no subsequent problems should arise. Light transmission loss in this situation can be easily resolved by optimizing the angle of incidence of the exposure light. Accordingly, it is surmised that regardless of whether the exposure target is a resist film, a photographic photosensitive plate, or an imaging screen, provided the target is inactive with respect to the immersion solvent, namely, is neither affected by the immersion solvent, nor affects the immersion solvent, then it is considered that there will be no change in the performance of the optical system. Accordingly, this factor requires no new test.

(ii) The effect of the resist film on the immersion solvent refers specifically to the leaching of components out of the resist film and into the solution, thereby altering the refractive index of the immersion solvent. If the refractive index of the immersion solvent changes, then it is absolutely clear from theory, even without conducting tests, that the optical resolution of the patterned exposure will be affected by that change. This factor can be adequately identified by confirming either a change in the composition of the immersion solvent or a change in the solvent refractive index as a result of leaching of a resist component upon immersion of the resist film into the immersion solvent, and there is no need to actually irradiate patterned light onto the resist and then develop the resist and determine the resolution.

In contrast, if patterned light is irradiated onto the resist film in the immersion solvent, and the resist is then developed and the resolution is determined, then even if a change in the resolution is detected, there is no way of distinguishing whether the change is a result of a degeneration in the immersion solvent affecting the resolution, a degeneration in the resist film affecting the resolution, or a combination of both factors.

(iii) Degeneration of the resist film caused by the immersion solvent, leading to a deterioration in the resolution, can be adequately ascertained by a simple evaluation wherein a treatment step for bringing an immersion solvent into contact with the resist film, for example by spraying in the form of a shower, is inserted between the selective exposure step and the post exposure baking (PEB) step, and the resist film is then developed, and the resolution of the resulting resist pattern is analyzed. Moreover, in this evaluation method, sprinkling the immersion solvent directly onto the resist film ensures that the immersion conditions are more stringent. If the exposure is conducted with the resist film in a state of complete immersion, then it is impossible to determine whether any change in resolution is an effect of a degeneration in the immersion solvent a result of a degeneration in the resist composition caused by the immersion solvent, or a combination of both factors.

The phenomena (ii) and (iii) above are inextricably linked, and can be identified by confirming a deterioration in either the pattern shape or the sensitivity caused by the action of the immersion solvent on the resist film. Accordingly, investigation of only the factor (iii) can be deemed to incorporate investigation of the factor (ii).

Based on these analyses, the suitability to immersion lithography of a resist film formed from a novel resist composition thought to be ideal for immersion lithography processes was confirmed by an evaluation test (hereafter referred to as the “evaluation test 1”), wherein a treatment step for bringing an immersion solvent into contact with the resist film, for example by spraying in the form of a shower, is inserted between the selective exposure step and the post exposure baking (PEB) step, and the resist film is then developed, and the resolution of the resulting resist pattern is analyzed.

In addition, in another evaluation method that represents a further development of the evaluation test 1, additional confirmation was made by an evaluation test that represents a simulation of an actual production process (hereafter referred to as the “evaluation test 2”), wherein the patterned exposure light is substituted with interference light from a prism, and the sample is placed in an actual state of immersion and exposed (a double beam interference exposure method).

### BEST MODE FOR CARRYING OUT THE INVENTION

As follows is a description of embodiments of the present invention.

### <<Silsesquioxane Resin>>

A silsesquioxane resin of the present invention contains the structural units represented by the aforementioned general formulas [1] and [2].

In this description, the term “structural unit” refers to a monomer unit that contributes to the formation of a polymer.

In the general formulas [1] and [2], R¹ and R² may be either the same group or different groups, and each represents a straight chain, branched, or cyclic saturated aliphatic hydrocarbon group, in which the number of carbon atoms, from the viewpoint of best controlling the solubility in the resist solvent and the molecular size, is preferably from 1 to 20, and even more preferably from 5 to 12. Cyclic saturated aliphatic hydrocarbon groups are particularly preferred, as they offer the advantages of generating silsesquioxane resins with good transparency to high energy light, high glass transition temperatures (Tg), and more ready control of the generation of acid from the acid generator during PEB.

As these cyclic saturated aliphatic hydrocarbon groups, either monocyclic groups or polycyclic groups can be used. Examples of polycyclic groups include groups in which two hydrogen atoms have been removed from a bicycloalkane, tricycloalkane, or tetracycloalkane or the like, and specific examples include groups in which two hydrogen atoms have been removed from a polycycloalkane such as adamantane, norbornane, isobornane, tricyclodecane or tetracyclododecane.

More specific examples of R¹ and R² include groups in which two hydrogen atoms have been removed from an alicyclic compound selected from a group consisting of compounds represented by the following formulas [3] to [8], and derivatives thereof.

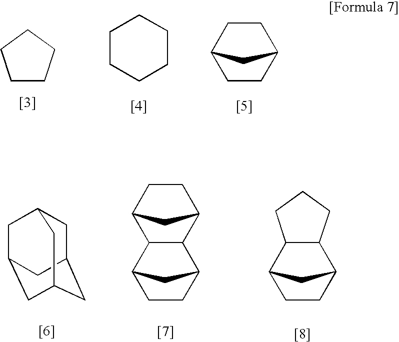

Here, the term “derivative” refers to an alicyclic compound of one of the formulas [3] to [8], wherein at least one of the hydrogen atoms has been substituted with a lower alkyl group of 1 to 5 carbon atoms such as a methyl group or ethyl group, an oxygen atom, or a halogen atom such as a fluorine, chlorine, or bromine atom.

Of the above groups, groups in which two hydrogen atoms have been removed from an alicyclic compound selected from the group consisting of compounds represented by the formulas [3] to [8] are preferred, as they exhibit superior transparency and are also readily available industrially.

R³ represents an acid dissociable, dissolution inhibiting group formed from a hydrocarbon group containing an aliphatic monocyclic or polycyclic group. This acid dissociable, dissolution inhibiting group has an alkali dissolution inhibiting effect that renders the entire silsesquioxane resin insoluble in alkali prior to exposure, but then dissociates under the action of acid generated from the acid generator following exposure, causing the entire silsesquioxane resin to become alkali soluble.

The silsesquioxane resin (A1) of the present invention contains acid dissociable, dissolution inhibiting groups formed from hydrocarbon groups containing bulky, aliphatic monocyclic or polycyclic groups such as those represented by the formulas [9] to [13] shown below, and as a result, when the silsesquioxane resin is used as the base resin in a positive resist composition, the dissolution inhibiting groups are far less likely to gasify following dissociation than conventional acid dissociable, dissolution inhibiting groups that contain no branched chain-like tertiary alkyl group, including straight chain alkoxyalkyl groups such as 1-ethoxyethyl groups, cyclic ether groups such as tetrahydropyranyl groups, or tert-butyl groups, thus enabling the aforementioned degas phenomenon to be prevented.

From the viewpoints of preventing gasification of the dissociated groups, while also ensuring suitable solubility levels in the resist solvent and the developing solution, the number of carbon atoms within the group R³ is preferably from 7 to 15, and even more preferably from 9 to 13.

Provided the acid dissociable, dissolution inhibiting group is formed from a hydrocarbon group containing an aliphatic monocyclic or polycyclic group, then the actual group can be selected appropriately in accordance with the exposure source, from the multitude of groups proposed for resist compositions resins for use with ArF excimer lasers and the like. Groups which form a cyclic tertiary alkyl ester with the carboxyl group of a (meth)acrylate are particularly well known.

Acid dissociable, dissolution inhibiting groups containing an aliphatic polycyclic group are particularly preferred. This aliphatic polycyclic group can be appropriately selected from the multitude of groups proposed for use within ArF resists. Examples of this aliphatic polycyclic group include groups in which in which one hydrogen atom has been removed from a bicycloalkane, tricycloalkane or tetracycloalkane or the like, and specific examples include groups in which one hydrogen atom has been removed from a polycycloalkane such as adamantane, norbornane, isobornane, tricyclodecane or tetracyclododecane.

More specific examples include any group selected from a group consisting of the following formulas [9] to [13].

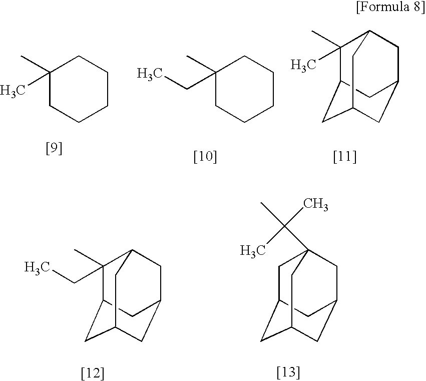

Silsesquioxane resins containing 2-methyl-2-adamantyl groups represented by the formula [11] and/or 2-ethyl-2-adamantyl groups represented by the formula [12] are particularly preferred, as they are resistant to degassing, and also exhibit superior resist characteristics such as resolution and heat resistance.

R⁴ represents a hydrogen atom, or a straight chain, branched, or cyclic alkyl group. From the viewpoint of solubility in the resist solvent, the number of carbon atoms within the alkyl group is preferably from 1 to 10, and lower alkyl groups of 1 to 4 carbon atoms are particularly desirable.

Specific examples of the alkyl group include a methyl group, ethyl group, propyl group, isopropyl group, n-butyl group, sec-butyl group, tert-butyl group, cyclopentyl group, cyclohexyl group, 2-ethylhexyl group, or n-octyl group.

The R⁴ group is selected appropriately in accordance with the desired alkali solubility of the silsesquioxane resin. The alkali solubility is highest when R⁴ is a hydrogen atom. Increased alkali solubility offers the advantage of improved sensitivity.

In contrast, as the number of carbon atoms within the alkyl group increases, or as the bulkiness of the group increases, the alkali solubility of the silsesquioxane resin decreases. As the alkali solubility decreases, the resistance to the alkali developing solution increases, generating an improvement in the exposure margin when the silsesquioxane resin is used to form a resist pattern, and lowering the degree of dimensional fluctuation accompanying exposure. Furthermore, developing irregularities are also reduced, meaning roughness within the edge portions of the formed resist pattern can also be improved.

X represents a straight chain, branched, or cyclic alkyl group, although preferably a straight chain alkyl group, in which at least one hydrogen atom has been substituted with a fluorine atom. From the viewpoints of ensuring a favorable glass transition temperature (Tg) for the silsesquioxane resin, and favorable solubility in the resist solvent, the number of carbon atoms within the alkyl group is preferably within a range from 1 to 8, and lower alkyl groups of 1 to 4 carbon atoms are particularly desirable.

Furthermore, increasing the number of hydrogen atoms that have been substituted with fluorine atoms is preferred as it improves the transparency relative to high energy light of no more than 200 nm and electron beams, and the most preferred groups are perfluoroalkyl groups in which all of the hydrogen atoms have been substituted with fluorine atoms.

In the general formulas [1] and [2], the X groups may be the same group or different groups. In other words, the plurality of X groups are mutually independent.

In terms of enabling ready dissociation of the acid dissociable, dissolution inhibiting group, m must be an integer from 1 to 3, and is preferably 1.

Specific examples of the silsesquioxane resin of the present invention include silsesquioxane resins containing the structural units represented by the following general formulas [14] and [15].

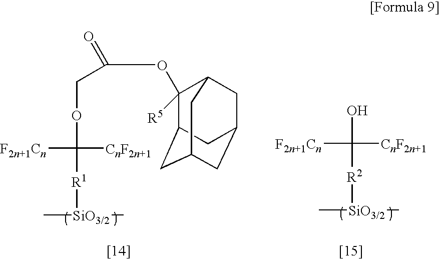

In these formulas, R¹ and R² are as defined above. R⁵ is a lower alkyl group, and preferably an alkyl group of 1 to 5 carbon atoms, and most preferably a methyl group or ethyl group. n is an integer from 1 to 8, and preferably from 1 to 2.

In other words, the general formulas [14] and [15] represent the general formulas [1] and [2] in those cases where R³ is a group represented by the formula [11] or [12], R⁴ is a hydrogen atom, X is an alkyl group in which all of the hydrogen atoms have been substituted with fluorine atoms, and m=1. R³ is most preferably the group of the formula [11].

Of all the structural units that make up the silsesquioxane resin of the present invention, the proportion of structural units represented by the general formulas [1] and [2] is typically within a range from 30 to 100 mol %, and preferably from 60 to 100 mol %. In other words, the silsesquioxane resin may contain up to 40 mol % of structural units other than the structural units represented by the general formulas [1] and [2]. A description of these optional structural units that are different from the structural units represented by the general formulas [1] and [2] is provided below.

Furthermore, the proportion of structural units represented by the general formula [1], relative to the combined total of structural units represented by the general formulas [1] and [2], is preferably within a range from 5 to 70 mol %, and even more preferably from 10 to 40 mol %. The proportion of structural units represented by the general formula [2] is preferably within a range from 30 to 95 mol %, and even more preferably from 60 to 90 mol %.

By ensuring that the proportion of structural units represented by the general formula [1] falls within the above range, the proportion of acid dissociable, dissolution inhibiting groups is determined naturally, and the change in alkali solubility of the silsesquioxane resin upon exposure is set to an ideal value for the base resin of a positive resist composition.

Provided their inclusion does not impair the effects of the present invention, the silsesquioxane resin may also contain, as the optional units described above, structural units that differ from the structural units represented by the general formulas [1] and [2]. Examples of these optional units include alkylsilsesquioxane units containing a lower alkyl group such as a methyl group, ethyl group, propyl group or butyl group, as represented by the following general formula [17], which are used in silsesquioxane resins used in ArF excimer laser resist compositions.

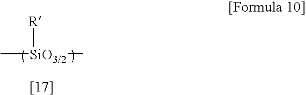

[wherein, R′ represents a straight chain or branched lower alkyl group, and preferably a lower alkyl group of 1 to 5 carbon atoms]

In those cases where a structural unit represented by the general formula [17] is used, then relative to the combined total of structural units represented by the general formulas [1], [2], and [17], the proportion of structural units represented by the general formula [1] is typically within a range from 5 to 30 mol %, and preferably from 8 to 20 mol %, the proportion of structural units represented by the general formula [2] is typically within a range from 40 to 80 mol %, and preferably from 50 to 70 mol %, and the proportion of structural units represented by the general formula [17] is typically within a range from 1 to 40 mol %, and preferably from 5 to 35 mol %.

There are no particular restrictions on the weight average molecular weight (Mw) (the polystyrene equivalent value determined by gel permeation chromatography, this also applies to all subsequent values) of the silsesquioxane resin of the present invention, although the value is preferably within a range from 2,000 to 15,000, and even more preferably from 3,000 to 8,000. If the weight average molecular weight is larger than this range, then the solubility within the resist solvent deteriorates, whereas if the value is smaller than the above range, there is a danger of a deterioration in the cross-sectional shape of the resist pattern.

Furthermore, although there are no particular restrictions on the ratio Mw/Mn (number average molecular weight), the ratio is preferably within a range from 1.0 to 6.0, and even more preferably from 1.1 to 2.5. If this ratio is larger than this range, then there is a danger of a deterioration in both the resolution and the pattern shape.

Production of a silsesquioxane resin of the present invention can usually be conducted using the general method used for the production of random polymers, and an example of the method is described below.

First, a single Si-containing monomer that yields the structural unit represented by the formula [2], or a mixture of two or more such monomers, is subjected to a dehydration-condensation in the presence of a catalyst, thereby yielding a polymer solution containing a polymer with a silsesquioxane as the basic skeleton. Next, a quantity of Br—(CH₂)ₘCOOR³ equivalent to 5 to 70 mol % of the aforementioned Si-containing monomer is dissolved in an organic solvent such as tetrahydrofuran, and the resulting solution is added dropwise to the polymer solution, thereby effecting an addition reaction that converts —OR⁴ to —O—(CH₂)ₘCOOR³.

Furthermore, in the case of a resin that contains a structural unit represented by the formula [17], synthesis can be conducted in the same manner as above, using a Si-containing monomer that yields the structural unit represented by the formula [2], and a Si-containing monomer that yields the structural unit represented by the formula [17].

As described above, a silsesquioxane resin of the present invention is effective in preventing the degas phenomenon that can occur after exposure during the formation of a resist pattern.

Furthermore, because the silsesquioxane resin of the present invention is a polymer containing, as the basic skeleton, a silsesquioxane structure made up of structural units represented by the formulas [1] and [2], and in some cases the formula [17], the transparency of the resin to high energy light of no more than 200 nm and electron beams is extremely high. Consequently, a positive resist composition containing a silsesquioxane resin of the present invention can be favorably employed for lithography using a light source with a shorter wavelength even than an ArF excimer laser, and in a single layer process, can be used for forming ultra fine resist patterns with line widths of no more than 150 nm, and even less than 120 nm. Furthermore, by using such a positive resist composition as the upper layer in a two-layer resist laminate described below, processes for forming ultra fine resist patterns of no more than 120 nm, and even 100 nm or less, can be realized.

### <<Positive Resist Composition>>

Component (A)

A positive resist composition according to the present invention comprises a resin component (A) that exhibits increased alkali solubility under the action of acid, and an acid generator component (B) that generates acid on exposure, wherein the component (A) contains an aforementioned silsesquioxane resin of the present invention (hereafter referred to as the silsesquioxane resin (A1)).

By using the silsesquioxane resin (A1) in the component (A), degassing can be prevented from occurring during resist pattern formation using a positive resist composition containing the silsesquioxane resin (A1). Furthermore, this positive resist composition displays a high level of transparency to high energy light of no more than 200 nm and electron beams, and enables the generation of high resolution patterns.

The component (A) may contain only the silsesquioxane resin (A1), or may be a mixed resin that also contains other resins as well as (A1). The proportion of (A1) within a mixed resin is preferably within a range from 50 to 95% by weight, and even more preferably from 70 to 90% by weight.

By ensuring the proportion of the silsesquioxane resin (A1) falls within the above range, a superior prevention of the degas phenomenon is realized, and in those cases where a two-layer resist laminate is formed, the upper layer provides excellent performance as a mask during dry etching of the lower resist layer.

As the optional resin component (A2) other than (A1), any of the resins typically used as base resins in chemically amplified resist compositions can be selected and used, in accordance with the light source used during resist pattern formation.

For example, in those cases where an ArF excimer laser is used, a mixed resin with a resin component (A2) containing a structural unit (a1) derived from a (meth)acrylate ester containing an acid dissociable, dissolution inhibiting group is preferred, as such a mixture enables an improvement in the heat resistance of the entire component (A), and also exhibits excellent resolution.

As the resin (A2), resins containing a structural unit (a1) derived from a (meth)acrylate ester containing an acid dissociable, dissolution inhibiting group, and a structural unit that is different from (a1) but is also derived from a (meth)acrylate ester, wherein the proportion of structural units derived from (meth)acrylate esters is at least 80 mol %, and even more preferably 90 mol % or higher (and most preferably 100 mol %), are particularly desirable.

The term “(meth)acrylic acid” refers to either one of, or both, methacrylic acid and acrylic acid. Similarly, the term “(meth)acrylate” refers to either one of, or both, methacrylate and acrylate.

Furthermore, in order to satisfy the required levels of resolution, dry etching resistance, and fine pattern shape, the resin (A2) preferably contains a combination of a plurality of monomer units that differ from the unit (a1) and provide a variety of different functions. Suitable monomer units include the structural units described below.

Structural units derived from a (meth)acrylate ester containing a lactone unit (hereafter referred to as (a2) or (a2) units).

Structural units derived from a (meth)acrylate ester containing a polycyclic group with an alcoholic hydroxyl group (hereafter referred to as (a3) or (a3) units).

Structural units containing a polycyclic group that differs from the acid dissociable, dissolution inhibiting group of the (a1) units, the lactone unit of the (a2) units, and the polycyclic group with an alcoholic hydroxyl group of the (a3) units (hereafter referred to as (a4) or (a4) units).

The units (a2), (a3), and/or (a4) can be combined appropriately in accordance with the characteristics required of the resin.

The component (A2) preferably contains the (a1) unit, and at least one unit selected from (a2), (a3), and (a4) units, as such resins provide superior resolution and resist pattern shape. Each of the units (a1) to (a4) may include a combination of a plurality of different units.

In the component (A2), of the total number of mols of structural units derived from methacrylate esters and the structural units derived from acrylate esters, the structural units derived from methacrylate esters preferably account for 10 to 85 mol %, and even more preferably from 20 to 80 mol %, whereas the structural units derived from acrylate esters preferably account for 15 to 90 mol %, and even more preferably from 20 to 80 mol %.

As follows is a detailed description of each of the above units (a1) to (a4).

[(a1) Units]

The (a1) unit is a structural unit derived from a (meth)acrylate ester containing an acid dissociable, dissolution inhibiting group.

There are no particular restrictions on the acid dissociable, dissolution inhibiting group of (a1), provided it displays an alkali dissolution inhibiting effect that renders the entire component (A2) alkali insoluble prior to exposure, but dissociates under the action of acid generated from the aforementioned component (B) following exposure, causing the entire component (A2) to become alkali soluble. Generally, groups which form a cyclic or chain-like tertiary alkyl ester with the carboxyl group of (meth)acrylic acid, tertiary alkoxycarbonyl groups, or chain-like alkoxyalkyl groups are the most widely used.

As the acid dissociable, dissolution inhibiting group within (a1), an acid dissociable, dissolution inhibiting group containing an aliphatic polycyclic group can be favorably used.

Examples of this polycyclic group include groups in which one hydrogen atom has been removed from a bicycloalkane, a tricycloalkane or a tetracycloalkane or the like, which may be either unsubstituted, or substituted with a fluorine atom or fluoroalkyl group. Specific examples include groups in which one hydrogen atom has been removed from a polycycloalkane such as adamantane, norbornane, isobornane, tricyclodecane or tetracyclododecane. These types of polycyclic groups can be appropriately selected from the multitude of groups proposed for use with ArF resists. Of these groups, adamantyl groups, norbornyl groups and tetracyclododecanyl groups are preferred in terms of industrial availability.

Ideal monomer units for the (a1) unit are shown below in [formula 11] through [formula 19].

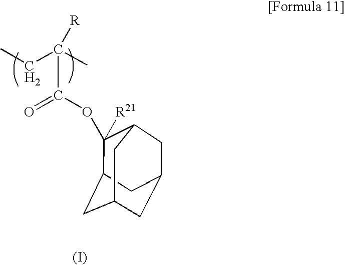

(wherein, R represents a hydrogen atom or a methyl group, and R²¹ represents a lower alkyl group)

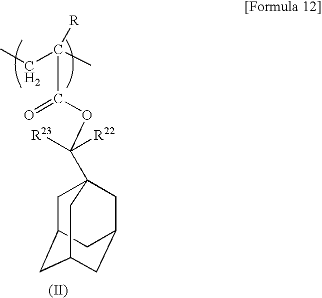

(wherein, R represents a hydrogen atom or a methyl group, and R²² and R²³ each represent, independently, a lower alkyl group)

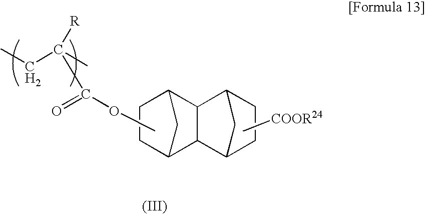

(wherein, R represents a hydrogen atom or a methyl group, and 124 represents a tertiary alkyl group)

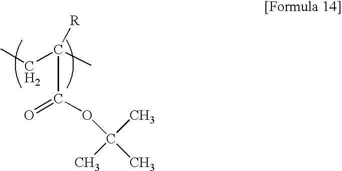

(wherein, R represents a hydrogen atom or a methyl group)

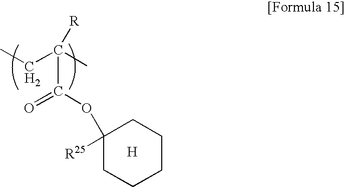

(wherein, R represents a hydrogen atom or a methyl group, and R²⁵ represents a methyl group)

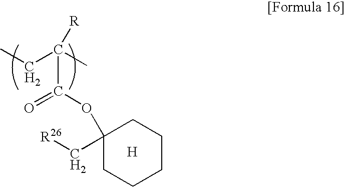

(wherein, R represents a hydrogen atom or a methyl group, and R²⁶ represents a lower alkyl group)

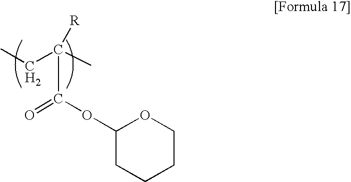

(wherein, R represents a hydrogen atom or a methyl group)

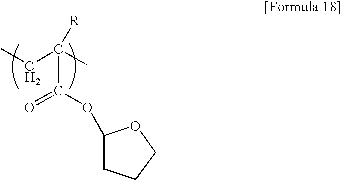

(wherein, t represents a hydrogen atom or a methyl group)

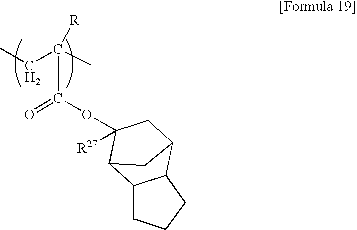

(wherein, R represents a hydrogen atom or a methyl group, and R²⁷ represents a lower alkyl group)

Within the above formulas, the groups R²¹ to R²³ and R²⁶ to R²⁷ each preferably represent a straight chain or branched lower alkyl group of 1 to 5 carbon atoms, and specific examples include a methyl group, ethyl group, propyl group, isopropyl group, n-butyl group, isobutyl group, tert-butyl group, pentyl group, isopentyl group and neopentyl group. From the viewpoint of industrial availability, a methyl group or an ethyl group is preferred.

Furthermore, R²⁴ represents a tertiary alkyl group such as a tert-butyl group or a tert-amyl group, although a tert-butyl group is preferred industrially.

As the (a1) unit, of all the units described above, structural units represented by the general formulas (I), (II) and (III) generate resist patterns that display particularly superior transparency, resolution, and dry etching resistance, and are consequently the most preferred.

[(a2) Units]

The (a2) unit contains a lactone unit, and is consequently effective in improving the hydrophilicity with the developing solution.

An (a2) unit of the present invention may be any unit that contains a lactone unit and is copolymerizable with the other structural units of the component (A).

Examples of suitable monocyclic lactone units include groups in which one hydrogen atom has been removed from γ-butyrolactone. Furthermore, examples of suitable polycyclic lactone units include groups in which one hydrogen atom has been removed from a lactone-containing polycycloalkane. In the lactone unit, the ring containing the —O—C(O)— structure is counted as the first ring. Accordingly, the case in which the only ring structure is the ring containing the —O—C(O)— structure is referred to as a monocyclic group, and groups containing other ring structures are described as polycyclic groups regardless of the structure of the other rings.

Ideal monomer units for the (a2) unit are shown below in the general formulas [formula 20] through [formula 22].

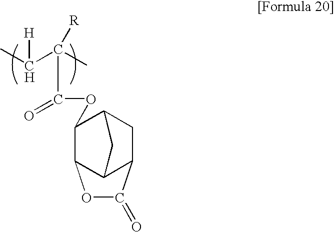

(wherein, R represents a hydrogen atom or a methyl group)

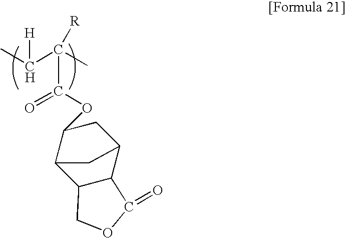

(wherein, R represents a hydrogen atom or a methyl group)

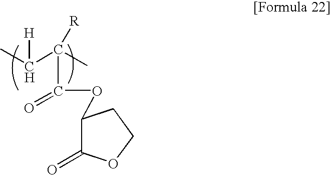

(wherein, R represents a hydrogen atom or a methyl group)

Of the above units, γ-butyrolactone esters of (meth)acrylic acid with an ester linkage at the α carbon atom, as shown in [formula 22], or norbornane lactone esters such as those shown in [formula 20] and [formula 21] are particularly preferred in terms of industrial availability.

[(a3) Units]

The (a3) unit is a structural unit derived from a (meth)acrylate ester containing a polycyclic group with an alcoholic hydroxyl group. Because the hydroxyl group of the alcoholic hydroxyl group-containing polycyclic group is a polar group, use of this unit results in an increased hydrophilicity for the entire component (A2) relative to the developing solution, and an improvement in the alkali solubility of the exposed portions. Accordingly, if the component (A2) contains (a3), there is a favorable improvement in the resolution.

As the polycyclic group in the (a3) unit, any polycyclic group can be appropriately selected from the various aliphatic polycyclic groups listed in the above description for the (a1) unit.

There are no particular restrictions on the alcoholic hydroxyl group-containing polycyclic group in the (a3) unit, and for example, a hydroxyl group-containing adamantyl group can be favorably used.

In addition, if this hydroxyl group-containing adamantyl group is a group represented by a general formula (IV) shown below, then the dry etching resistance improves, as does the verticalness of the cross-sectional shape of the pattern, both of which are desirable.

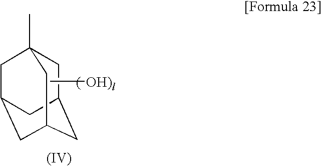

(wherein, n represents an integer from 1 to 3)

The (a3) unit may be any unit which contains an aforementioned alcoholic hydroxyl group-containing polycyclic group, and is copolymerizable with the other structural units of the component (A2).

Specifically, structural units represented by a general formula (V) shown below are preferred.

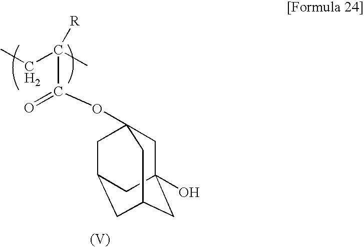

(wherein, R represents a hydrogen atom or a methyl group)
[(a4) Units]

In the (a4) unit, a polycyclic group that “differs from the acid dissociable, dissolution inhibiting group, the lactone unit, and the alcoholic hydroxyl group-containing polycyclic group” means that in the component (A2), the polycyclic group of the (a4) unit is a polycyclic group which does not duplicate the acid dissociable, dissolution inhibiting group of the (a1) unit, the lactone unit of the (a2) unit or the alcoholic hydroxyl group-containing polycyclic group of the (a3) unit, and also means that the (a4) unit does not support the acid dissociable, dissolution inhibiting group of the (a1) unit, the lactone unit of the (a2) unit, or the alcoholic hydroxyl group containing polycyclic group of the (a3) unit, which constitute the component (A2).

There are no particular restrictions on the polycyclic group of the (a4) unit provided it is selected so as not to duplicate any of the structural units used in the units (a1) to (a3) of a single component (A2). For example, as the polycyclic group in the (a4) unit, the same aliphatic polycyclic groups listed in the above description for the (a 1) unit can be used, and any of the multitude of materials conventionally used for ArF positive resist materials can be used.

From the viewpoint of industrial availability, one or more groups selected from amongst tricyclodecanyl groups, adamantyl groups, and tetracyclododecanyl groups is preferred.

The (a4) unit may be any unit which contains an aforementioned polycyclic group, and is copolymerizable with the other structural units of the component (A).

Preferred examples of (a4) are shown below in [formula 25] through [formula 27].

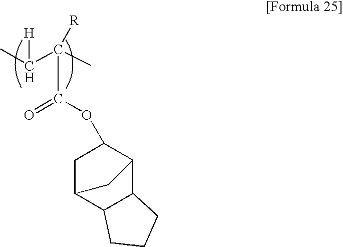

(wherein, R represents a hydrogen atom or a methyl group)

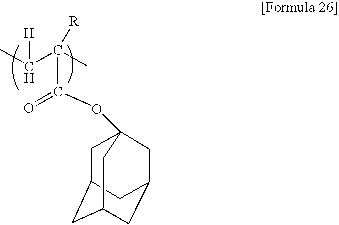

(wherein, R represents a hydrogen atom or a methyl group)

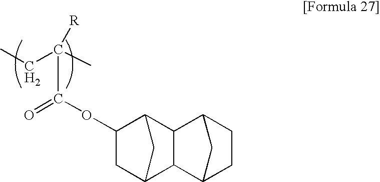

(wherein, R represents a hydrogen atom or a methyl group)

In a positive resist composition of the present invention, component (A2) compositions in which the (a1) unit accounts for 20 to 60 mol %, and preferably from 30 to 50 mol %, of the combined total of all the structural units of the component (A2) display excellent resolution, and are consequently preferred.

Furthermore, compositions in which the (a2) unit accounts for 20 to 60 mol %, and preferably from 30 to 50 mol %, of the combined total of all the structural units of the component (A2) display excellent resolution, and are consequently preferred.

Furthermore, in those cases where the (a3) unit is used, compositions in which the (a3) unit accounts for 5 to 50 mol %, and preferably from 10 to 40 mol %, of the combined total of all the structural units of the component (A2) display excellent resist pattern shape, and are consequently preferred.

In those cases where the (a4) unit is used, compositions in which the (a4) unit accounts for 1 to 30 mol %, and preferably from 5 to 20 mol %, of the combined total of all the structural units of the component (A2) offer superior resolution for isolated patterns through to semi-dense patterns, and are consequently preferred.

The (a1) unit can be appropriately combined with at least one unit selected from the (a2), (a3), and (a4) units, in accordance with the desired characteristics, and a tertiary polymer containing an (a1) unit, together with (a2) and (a3) units, is particularly preferred as it exhibits excellent resist pattern shape, exposure margin, heat resistance, and resolution. In such a polymer, the respective proportions of each of the structural units (a1) to (a3) are preferably from 20 to 60 mol % for (a1), from 20 to 60 mol % for (a2), and from 5 to 50 mol % for (a3).

Furthermore, there are no particular restrictions on the weight average molecular weight of the component (A2) in the present invention, although values are typically within a range from 5,000 to 30,000, and preferably from 8,000 to 20,000. If the molecular weight is greater than this range, then the solubility of the component in the resist solvent deteriorates, whereas if the molecular weight is too small, there is a danger of a deterioration in the dry etching resistance and the cross sectional shape of the resist pattern.

The resin component (A2) in the present invention can be produced easily by a conventional radical polymerization of the monomer corresponding with the (a1) unit, and where necessary monomers corresponding with the (a2), (a3), and/or (a4) units, using a radical polymerization initiator such as azobisisobutyronitrile (AIBN).

Component (B)

As the component (B), a compound appropriately selected from known materials used as acid generators in conventional chemically amplified resists can be used.

Examples of suitable compounds for the component (B) include onium salts such as diphenyliodonium trifluoromethanesulfonate, (4-methoxyphenyl)phenyliodonium trifluoromethanesulfonate, bis(p-tert-butylphenyl)iodonium trifluoromethanesulfonate, triphenylsulfonium trifluoromethanesulfonate, (4-methoxyphenyl)diphenylsulfonium trifluoromethanesulfonate, (4-methylphenyl)diphenylsulfonium nonafluorobutanesulfonate, (p-tert-butylphenyl)diphenylsulfonium trifluoromethanesulfonate, diphenyliodonium nonafluorobutanesulfonate, bis(p-tert-butylphenyl)iodonium nonafluorobutanesulfonate, triphenylsulfonium nonafluorobutanesulfonate, (4-trifluoromethylphenyl)diphenylsulfonium trifluoromethanesulfonate, (4-trifluoromethylphenyl)diphenylsulfonium nonafluorobutanesulfonate, and tri(p-tert-butylphenyl)sulfonium trifluoromethanesulfonate.

Of these onium salts, triphenylsulfonium salts are resistant to decomposition and unlikely to generate organic gases, and are consequently preferred. The quantity of triphenylsulfonium salts relative to the total quantity of the component (B) is preferably within a range from 50 to 100 mol %, and even more preferably from 70 to 100 mol %, and is most preferably 100 mol %.

Of the above onium salts, iodonium salts may give rise to organic gases containing iodine.

Furthermore, of the triphenylsulfonium salts, triphenylsulfonium salts represented by the general formula [16] shown below, which incorporate a perfluoroalkylsulfonate ion as the anion, provide improved levels of sensitivity, and are consequently preferred.

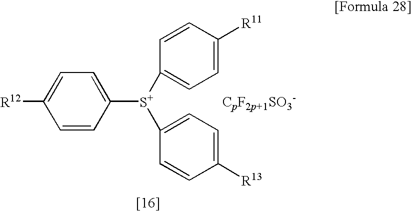

[wherein, R¹¹, R¹², and R¹³ each represent, independently, a hydrogen atom, a lower alkyl group of 1 to 8, and preferably 1 to 4, carbon atoms, or a halogen atom such as a chlorine, fluorine, or bromine atom; and p represents an integer from 1 to 12, and preferably from 1 to 8, and even more preferably from 1 to 4]

The component (B) can be used either alone, or in combinations of two or more different compounds.

The quantity used of the component (B) is typically within a range from 0.5 to 30 parts by weight, and preferably from 1 to 10 parts by weight, per 100 parts by weight of the component (A). At quantities less than 0.5 parts by weight, pattern formation does not proceed satisfactorily, whereas if the quantity exceeds 30 parts by weight, achieving a uniform solution becomes difficult, and there is a danger of a deterioration in the storage stability.

A positive resist composition of the present invention can be produced by dissolving the component (A) and the component (B), together with any optional components described below, in an organic solvent.

The organic solvent may be any solvent capable of dissolving the component (A) and the component (B) to generate a uniform solution, and one or more solvents selected from known materials used as the solvents for conventional chemically amplified resists can be used.

In a photoresist composition according to the present invention, the quantity of the organic solvent component is generally sufficient to produce a solid fraction concentration within the resist composition of 3 to 30% by weight, with the actual value set in accordance with the resist film thickness.

Specific examples of the solvent include ketones such as acetone, methyl ethyl ketone, cyclohexanone, methyl isoamyl ketone and 2-heptanone; polyhydric alcohols and derivatives thereof such as ethylene glycol, ethylene glycol monoacetate, diethylene glycol, diethylene glycol monoacetate, propylene glycol, propylene glycol monoacetate, dipropylene glycol, or the monomethyl ether, monoethyl ether, monopropyl ether, monobutyl ether or monophenyl ether of dipropylene glycol monoacetate; cyclic ethers such as dioxane; and esters such as methyl lactate, ethyl lactate, methyl acetate, ethyl acetate, butyl acetate, methyl pyruvate, ethyl pyruvate, methyl methoxypropionate, and ethyl ethoxypropionate. These organic solvents can be used alone, or as a mixed solvent of two or more different solvents.

Furthermore, in a positive resist composition of the present invention, in order to improve the resist pattern shape and the post exposure stability of the latent image formed by the pattern-wise exposure of the resist layer, a known amine, and preferably a secondary lower aliphatic amine or tertiary lower aliphatic amine, or an organic acid such as an organic carboxylic acid or a phosphorus oxo-acid or derivative thereof can also be added as a quencher.

Here, a lower aliphatic amine refers to an alkyl or alkyl alcohol amine of no more than 5 carbon atoms, and examples of these secondary and tertiary amines include trimethylamine, diethylamine, triethylamine, di-n-propylamine, tri-n-propylamine, tripentylamine, diethanolamine and triethanolamine, and alkanolamines such as triethanolamine are particularly preferred. These may be used either alone, or in combinations of two or more different compounds. These amines are typically added in a quantity of 0.01 to 2.0% by weight relative to the quantity of the component (A). As the organic carboxylic acid, malonic acid, citric acid, malic acid, succinic acid, benzoic acid, and salicylic acid are ideal.

Examples of suitable phosphorus oxo acids or derivatives thereof include phosphoric acid or derivatives thereof such as esters, including phosphoric acid, di-n-butyl phosphate and diphenyl phosphate; phosphonic acid or derivatives thereof such as esters, including phosphonic acid, dimethyl phosphonate, di-n-butyl phosphonate, phenylphosphonic acid, diphenyl phosphonate and dibenzyl phosphonate; and phosphinic acid or derivatives thereof such as esters, including phosphinic acid and phenylphosphinic acid, and of these, phosphonic acid is particularly preferred.

The organic acid is typically used in a quantity within a range from 0.01 to 5.0 parts by weight per 100 parts by weight of the component (A). These acids may be used either alone, or in combinations of two or more different compounds. These organic acids are preferably used in a quantity equivalent to no more than an equimolar ratio with the above amines.

Other miscible additives can also be added to a positive resist composition of the present invention according to need, including additive resins for improving the properties of the resist film, surfactants for improving the ease of application, dissolution inhibitors, plasticizers, stabilizers, colorants and halation prevention agents.

By using a positive resist composition with the type of structure described above, post-exposure degassing can be reduced at the time of resist pattern formation. Furthermore, the composition also displays excellent transparency to high energy light of no more than 200 nm and electron beams, and provides a high level of resolution.

### <<Resist Laminate>>

A resist laminate of the present invention includes a lower resist layer, which is insoluble in the alkali developing solution but can be dry etched, and an upper resist layer formed from a positive resist composition of the present invention laminated on top of a support.

As the support, conventional materials can be used without any particular restrictions, and suitable examples include substrates for electronic componentry, as well as substrates on which a predetermined wiring pattern has already been formed.

Specific examples of suitable substrates include metal-based substrates such as silicon wafers, copper, chrome, iron, and aluminum, as well as glass substrates.

Suitable materials for the wiring pattern include copper, aluminum, nickel, and gold.

The lower resist layer is an organic film which is insoluble in the alkali developing solution used for post-exposure developing, but can be etched by conventional dry etching.

With this type of lower resist layer, first, normal photolithography techniques are used to expose and then alkali-develop only the upper resist layer, thereby forming a resist pattern, and by then using this resist pattern as a mask to conduct etching of the lower resist layer, the resist pattern of the upper resist layer is transferred to the lower resist layer. As a result a resist pattern with a high aspect ratio can be formed without pattern collapse of the resist pattern.

The resist material for forming the lower resist layer, although termed a resist, does not require the photosensitivity needed for the upper resist layer, and can use the type of material typically used as a base material in the production of semiconductor elements and liquid crystal display elements.

Furthermore, because the resist pattern of the upper resist layer must be transferred to the lower resist layer, the lower resist layer should preferably be formed from a material that is able to be etched by oxygen plasma etching.

As this material, materials containing at least one resin selected from a group consisting of novolak resins, acrylic resins, and soluble polyimides as the primary component are preferred, as they are readily etched by oxygen plasma treatment, and also display good resistance to fluorocarbon-based gases, which are used in subsequent processes for tasks such as etching the silicon substrate.

Of these materials, novolak resins, and acrylic resins containing an alicyclic region or aromatic ring on a side chain are cheap, widely used, and exhibit excellent resistance to the dry etching of subsequent processes, and are consequently preferred.

As the novolak resin, any of the resins typically used in positive resist compositions can be used, and positive resists for i-line or g-line radiation containing a novolak resin as the primary component can also be used.

A novolak resin is a resin obtained from an addition condensation of an aromatic compound containing a phenolic hydroxyl group (hereafter, simply referred to as a phenol) and an aldehyde, in the presence of an acid catalyst.

Examples of the phenol used include phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethylphenol, 3,4,5-trimethylphenol, p-phenylphenol, resorcinol, hydroquinone, hydroquinone monomethyl ether, pyrogallol, fluoroglucinol, hydroxydiphenyl, bisphenol A, gallic acid, gallic esters, α-naphthol, and β-naphthol.

Furthermore, examples of the aldehyde include formaldehyde, furfural, benzaldehyde, nitrobenzaldehyde, and acetaldehyde.

There are no particular restrictions on the catalyst used in the addition condensation reaction, and suitable acid catalysts include hydrochloric acid, nitric acid, sulfuric acid, formic acid, oxalic acid, and acetic acid.

The weight average molecular weight of the novolak resin is typically within a range from 3,000 to 10,000, and preferably from 6,000 to 9,000, and most preferably from 7,000 to 8,000. If the weight average molecular weight is less than 3,000, then the resin tends to lose resistance to the alkali developing solution, whereas if the weight average molecular weight exceeds 10,000, the resin tends to become more difficult to dry etch, which is undesirable.

Novolak resins for use in the present invention can use commercially available resins.

As the acrylic resin, any of the resins typically used in positive resist compositions can be used, and suitable examples include acrylic resins containing a structural unit derived from a polymerizable compound with an ether linkage, and a structural unit derived from a polymerizable compound containing a carboxyl group.

Examples of the polymerizable compound containing an ether linkage include (meth)acrylic acid derivatives containing both an ether linkage and an ester linkage such as 2-methoxyethyl (meth)acrylate, methoxytriethylene glycol (meth)acrylate, 3-methoxybutyl (meth)acrylate, ethylcarbitol (meth)acrylate, phenoxypolyethylene glycol (meth)acrylate, methoxypolypropylene glycol (meth)acrylate, and tetrahydrofurfuryl (meth)acrylate. These compounds can be used either alone, or in combinations of two or more different compounds.

Examples of the polymerizable compound containing a carboxyl group include monocarboxylic acids such as acrylic acid, methacrylic acid, and crotonic acid; dicarboxylic acids such as maleic acid, fumaric acid, and itaconic acid; and compounds containing both a carboxyl group and an ester linkage such as 2-methacryloyloxyethylsuccinic acid, 2-methacryloyloxyethylmaleic acid, 2-methacryloyloxyethylphthalic acid, and 2-methacryloyloxyethylhexahydrophthalic acid, although of these, acrylic acid and methacrylic acid are preferred. These compounds can be used either alone, or in combinations of two or more different compounds.

The soluble polymide refers to polyimides that can be converted to liquid form in the type of organic solvents described above.

In a resist laminate of the present invention, giving due consideration to the ideal balance between the targeted aspect ratio and the throughput, which is affected by the dry etching time required for the lower resist layer, the combined thickness of the upper resist layer and the lower resist layer is preferably a total of no more than 15 μm, and is preferably from 0.1 to 5 μm.

The thickness of the upper resist layer is preferably within a range from 50 nm to 1 μm, and even more preferably from 70 to 250 nm. By ensuring that the thickness of the upper resist layer falls within this range, the resist pattern can be formed with a high level of resolution, while a satisfactory level of resistance to dry etching can also be achieved.

The thickness of the lower resist layer is preferably within a range from 100 nm to 14 μm, and even more preferably from 200 to 500 nm. By ensuring that the thickness of the lower resist layer falls within this range, a resist pattern with a high aspect ratio can be formed, while a satisfactory level of etching resistance to subsequent substrate etching can also be ensured.

The resist laminate of the present invention includes both resist laminates in which a resist pattern has been formed in the upper resist layer and the lower resist layer, as well as laminates in which no resist pattern has been formed.

### <<Method of Forming Resist Pattern>>

A method of forming a resist pattern according to the present invention can be conducted, for example, in the manner described below.

First, a resist composition or resin solution for forming the lower resist layer is applied to the top of a substrate such as a silicon wafer using a spinner or the like, and a prebake treatment is then performed, preferably at a temperature of 200 to 300° C., for a period of 30 to 300 seconds, and preferably from 60 to 180 seconds, thus forming a lower resist layer.

An organic or inorganic anti-reflective film may also be provided between the lower resist layer and the upper resist layer.

Next, a positive resist composition of the present invention is applied to the surface of the lower resist layer using a spinner or the like, and a prebake treatment is then performed at a temperature of 80 to 150° C. for a period of 40 to 120 seconds, and preferably from 60 to 90 seconds, thus forming an upper resist layer and completing preparation of a resist laminate of the present invention.

This resist laminate is then selectively exposed with an ArF exposure apparatus or the like, by irradiating ArF excimer laser light through a desired mask pattern, and PEB (post exposure baking) is then conducted under temperature conditions of 80 to 150° C. for 40 to 120 seconds, and preferably for 60 to 90 seconds.

Subsequently, the resist laminate is developed using an alkali developing solution such as an aqueous solution of tetramethylammonium hydroxide with a concentration of 0.05 to 10% by weight, and preferably from 0.05 to 3% by weight. In this manner, a resist pattern (I) that is faithful to the mask pattern can be formed in the upper resist layer.

As the light source used for the exposure, an ArF excimer laser is particularly effective, but longer wavelength light sources such as a KrF excimer laser, or shorter wavelength light sources such as a F₂ excimer laser, EUV (extreme ultraviolet), VUV (vacuum ultraviolet), electron beam, X-ray or soft X-ray radiation can also be used effectively.

Next, the obtained resist pattern (1) is used as a mask pattern for conducting dry etching of the lower resist layer, thereby forming a resist pattern (II) in the lower resist layer.

As the dry etching method, conventional methods including chemical etching such as down-flow etching or chemical dry etching; physical etching such as sputter etching or ion beam etching; or chemical-physical etching such as RIE (reactive ion etching) can be used.

The most typical type of dry etching is parallel plate RIE. In this method, first, a resist laminate is placed inside the RIE apparatus chamber, and the required etching gas is introduced. A high frequency voltage is then applied within the chamber, between an upper electrode and the resist laminate holder which is positioned parallel to the electrode, and this causes the generation of an etching gas plasma. The plasma contains charged particles such as positive and negative ions and electrons, as well as electrically neutral active seeds. As these etching seeds adsorb to the lower resist layer, a chemical reaction occurs, and the resulting reaction product breaks away from the surface and is discharged externally, causing the etching to proceed.

As the etching gas, oxygen or sulfur dioxide or the like are possible, although oxygen is preferred, as oxygen plasma etching provides a high level of resolution, the silsesquioxane resin (A1) of the present invention displays favorable etching resistance to oxygen plasma, and oxygen plasma is also widely used.

According to a method of forming a resist pattern according to the present invention, the degas phenomenon that can occur after exposure during the formation of a resist pattern is almost non-existent. Furthermore, the shape of the resist pattern formed using such a method has a high aspect ratio, suffers no pattern collapse, and provides a high degree of verticalness. Furthermore, a method of forming a resist pattern of the present invention enables the formation of resist patterns with ultra fine widths of no more than 100 nm, and even 65 nm or less, using high energy light of no more than 200 nm, such as an ArF excimer laser, or an electron beam.

<<Positive Resist Composition containing Silsesquioxane Resin, and Method of Forming a Resist Pattern using that Positive Resist Composition>>

A positive resist composition of the fifth aspect of the present invention can also be favorably used in the immersion lithography (also known as immersion exposure) method disclosed in the aforementioned non-patent reference 1, non-patent reference 2, and non-patent reference 3. This is a method in which, during exposure, the region between the lens and the resist layer disposed on top of the wafer, which has conventionally been filled with air or an inert gas such as nitrogen, is filled with a solvent such as pure water or a fluorine-based inert liquid, which has a larger refractive index than the refractive index of air. By filling this region with this type of solvent, it is claimed that higher resolutions equivalent to those obtained using a shorter wavelength light source or a larger NA lens can be obtained using the same exposure light source wavelength, with no reduction in the depth of focus range.

Using this type of immersion lithography, resist patterns with higher resolution and a superior depth of focus can be formed at low cost, using lenses mounted in conventional apparatus, and consequently the method is attracting considerable attention.

In other words, a positive resist composition according to the fifth aspect of the present invention is a resist composition used in a method of forming a resist pattern that includes an immersion lithography step, wherein if the sensitivity when a 1:1 line and space resist pattern of 130 nm is formed by a normal exposure lithography process using a light source with a wavelength of 193 nm is termed X1, and the sensitivity when an identical 1:1 line and space resist pattern of 130 nm is formed by a simulated immersion lithography process in which a step for bringing a solvent for the immersion lithography in contact with the resist film is inserted between the selective exposure step and the post exposure baking (PEB) step of a normal exposure lithography process using a light source with a wavelength of 193 nm is termed X2, then the resist composition is a positive resist composition containing a silsesquioxane resin as the resin component, for which the absolute value of [(X2/X1)−1]×100 is no more than 8.0.

More specifically, the immersion lithography is used in a method of forming a resist pattern, wherein during the immersion lithography step, the region between the resist layer formed from a positive resist composition containing the aforementioned silsesquioxane resin, and the lens at the lowermost point of the exposure apparatus is filled with a solvent which has a larger refractive index than the refractive index of air.

As the silsesquioxane resin, resins containing at least a silsesquioxane unit containing an acid dissociable, dissolution inhibiting group, and a silsesquioxane unit containing an alcoholic hydroxyl group are preferred. Silsesquioxane resins which also contain an alkylsilsesquioxane unit are also desirable. Particularly preferred resins include the silsesquioxane resins of the first aspect of the present invention.

By preparing a positive resist composition containing a resin component that includes this type of silsesquioxane resin, then if the sensitivity when a 1:1 line and space resist pattern of 130 nm is formed by a normal exposure lithography process using a light source with a wavelength of 193 nm is termed X1, and the sensitivity when an identical 1:1 line and space resist pattern of 130 nm is formed by a simulated immersion lithography process in which a step for bringing a solvent for the immersion lithography in contact with the resist film is inserted between the selective exposure step and the post exposure baking (PEB) step of a normal exposure lithography process using a light source with a wavelength of 193 nm is termed X2, the absolute value of [(X2/X1)−1]×100 can be maintained at no more than 8.0.

Provided this absolute value is no more than 8.0, the resist is ideal for use with immersion lithography. Specifically, the resist is resistant to any deleterious effects of the immersion solvent enabling the formation of a resist with excellent sensitivity and resist pattern profile shape. The smaller this absolute value is the better, and values of 5 or less are preferred, with values of no more than 3, and as close as possible to zero, being the most desirable.

As the resin component of this positive resist composition, by using a mixed resin containing the silsesquioxane resin and a resin component (A2) containing a structural unit (a1) derived from a (meth)acrylate ester containing an acid dissociable, dissolution inhibiting group, as in the second aspect of the present invention, the resolution and heat resistance can be favorably improved.

A positive resist composition according to the fifth aspect of the present invention is useful as the positive resist composition used in a method of forming a resist pattern that includes an immersion lithography step. This immersion lithography is a method in which the region between the resist layer formed from the positive resist composition, and the lens at the lowermost point of the exposure apparatus is filled with a solvent which has a larger refractive index than the refractive index of air.

Furthermore, this type of positive resist composition can also be used in a method of forming a resist pattern that includes the above type of immersion lithography step.

In the fifth aspect of the present invention, the normal exposure lithography process using a light source with a wavelength of 193 nm refers to a conventional lithography process, namely, sequential steps for resist application, prebaking, selective exposure, post exposure baking and alkali developing, which is conducted using an ArF excimer laser with a wavelength of 193 nm as the light source, by performing a normal exposure with the region between the exposure apparatus lens and the resist layer disposed on top of the wafer filled with air or an inert gas such as nitrogen. In some cases, a post bake step may also be provided following the alkali developing, and an organic or inorganic anti-reflective film may also be provided between the substrate and the applied layer of the resist composition.

The sensitivity X1 when a 130 nm 1:1 line and space resist pattern (hereafter abbreviated as “130 nm L&S”) is formed by this type of normal exposure lithography process refers to the exposure dose for forming a 130 nm L&S, which is a widely-used value by those skilled in the art, and is self-explanatory.

To describe this sensitivity briefly for the sake of thoroughness, the exposure dose is placed along the horizontal axis, the resist line width formed using that exposure dose is placed on the vertical axis, and a logarithmic approximation curve is obtained from the plot using the method of least squares.

The formula is represented by Y=aLoge(X1)+b, wherein X1 represents the exposure dose, Y represents the resist line width, and a and b are constants. If this formula is rearranged and converted to a formula representing X1, the formula

X1=Exp[(Y−b)/a] is obtained. If the value Y=130 (nm) is introduced into this formula, then the calculated ideal sensitivity X1 can be determined.

The conditions during this process, namely the rotational speed during application of the resist, the prebake temperature, the exposure conditions, the post exposure baking conditions, and the alkali developing conditions can all be set to conventionally used conditions, and are self-evident for forming a 130 nm L&S. Specifically, a silicon wafer with a diameter of 8 inches is used as the substrate, the rotational speed is set to approximately 1,000 to 4,000 rpm, or more specifically to approximately 1,500 to 3,500 rpm, or even more specifically to approximately 2000 rpm, and the prebake temperature is set within a range from 70 to 140° C., and preferably from 95 to 110° C. (setting the temperature to a level that enables a 1:1 ratio for a 130 nm line and space pattern is self-evident to those skilled in the art), and this enables a 6 inch diameter resist film with a (resist) film thickness of 80 to 250 nm, or more specifically of 150 nm, to be formed concentrically on top of the substrate.

The exposure conditions involve exposure through a mask, using an ArF excimer laser exposure apparatus with a wavelength of 193 nm manufactured by Nikon Corporation or Canon Inc. or the like (NA 0.60), or more specifically the exposure apparatus NSR-S302 (manufactured by Nikon Corporation, NA (numerical aperture)=0.60, ⅔ annular illumination). A normal binary mask is used as the mask in the selective exposure. A phase shift mask may also be used for this mask.

The post exposure baking uses a temperature within a range from 70 to 140° C., and preferably from 90 to 100° C. (setting the temperature to a level that enables a 1:1 ratio for a 130 nm line and space pattern is self-evident to those skilled in the art), and the conditions for the alkali developing involve immersing the substrate in a 2.38% by weight developing solution of TMAH (tetramethylammonium hydroxide) at a temperature of 23° C. for a period of 15 to 90 seconds, or more specifically 60 seconds, and then rinsing the substrate with water.

In addition, in the fifth aspect of the present invention, the simulated immersion lithography process refers to a process in which a step for bringing an immersion lithography solvent in contact with the resist film is inserted between the selective exposure step and the post exposure baking (PEB) step of a normal exposure lithography process that uses the same 193 nm ArF excimer laser described above as the light source.

Specifically, the simulated process involves sequential steps for resist application, prebaking, selective exposure, a step for bringing the immersion lithography solvent in contact with the resist film, post exposure baking, and alkali developing. In some cases, a post bake step may also be provided following the alkali developing.

[The term “contact” may involve immersing the selectively exposed resist film provided on top of the substrate in the immersion lithography solvent, or may involve spraying the immersion lithography solvent onto the resist in the form of a shower. The temperature during this step is preferably 23° C. If the solvent is sprayed on like a shower, then the substrate can be rotated at a speed of 300 to 3,000 rpm, and preferably from 500 to 2,500 rpm.]

The conditions for the contact described above are as follows. Pure water is dripped onto the center of the substrate from a rinse nozzle, while the wafer and the attached exposed resist film are rotated; rotational speed of the substrate on which the resist is formed: 500 rpm; solvent: pure water; rate of dropwise addition of the solvent: 1.0 L/min; solvent dripping time: 2 to 5 minutes; solvent and resist contact temperature: 23° C.

The sensitivity X2 when a 130 nm L&S resist pattern is formed using this type of simulated immersion lithography process is similar to the value of X1 described above, in that it represents the exposure dose for forming the 130 nm L&S, which is a widely used value by those skilled in the art.

The conditions during this process (the rotational speed during application of the resist, the prebake temperature, the exposure conditions, the post exposure baking conditions, and the alkali developing conditions) are also similar to the case of X1 described above.

In the fifth aspect of the present invention, the absolute value of [(X2/X1)−1]×100 must be no more than 8.0, and this absolute value is self-evident if the values of X2 and X1 are determined in the manner described above.

Furthermore, in the sixth aspect of the present invention, it can be advantageous to conduct the immersion lithography with a protective film formed from a fluorine-based resin provided on top of the resist film. In other words, first, the resist film is provided on the substrate. Subsequently, a protective film is provided on top of the resist film, and an immersion lithography liquid is then positioned in direct contact with the protective film. The resist film is then selectively exposed through the liquid and the protective film, and post exposure baking is then performed. Subsequently, the protective film is removed, and the resist film is then developed to form the resist pattern.

Desirable characteristics for the protective film include favorable transparency relative to the exposure light, being essentially incompatible with the liquid used for the immersion lithography, and undergoing no mixing with the resist film. The protective film must also exhibit good adhesion to the resist film, and favorable removability from the resist film. Examples of protective materials capable of forming a protective film equipped with the above characteristics include compositions formed by dissolving a fluorine-based resin in a fluorine-based solvent.

As the fluorine-based resin, chain-like perfluoroalkylpolyethers, cyclic perfluoroalkylpolyethers, polychlorotrifluoroethylene, polytetrafluoroethylene, copolymers of tetrafluoroethylene and perfluoroalkoxyethylenes, and copolymers of tetrafluoroethylene and hexafluoropropylene can be used.

From a practical viewpoint, commercially available products including chain-like perfluoroalkylpolyethers such as Demnum S-20, Demnum S-65, Demnum S-100, and Demnum S-200 (all manufactured by Daikin Industries, Ltd.), and cyclic perfluoroalkylpolyethers such as the Cytop series (manufactured by Asahi Glass Co., Ltd.), Teflon (R)-AF1600 and Teflon (R)-AF2400 (both manufactured by DuPont) can be used.

Of the above fluorine-based resins, mixed resins containing a chain-like perfluoroalkylpolyether and a cyclic perfluoroalkylpolyether are ideal.

As the aforementioned fluorine-based solvent, any solvent capable of dissolving the above fluorine-based resins can be used without any particular restrictions, and suitable examples include fluorine-based solvents, including perfluoroalkanes or perfluorocycloalkanes such as perfluorohexane and perfluoroheptane, perfluoroalkenes in which a double bond remains within one of the above alkanes, as well as perfluoro cyclic ethers such as perfluorotetrahydrofuran and perfluoro(2-butyltetrahydrofuran), perfluorotributylamine, perfluorotetrapentylamine, and perfluorotetrahexylamine.

Furthermore, other organic solvents or surfactants or the like that exhibit suitable co-solubility with these fluorine-based solvents can also be mixed into the solvent as appropriate.

There are no particular restrictions on the concentration of the fluorine-based resin, provided it is within a range that enables formation of a film, but considering factors such as ease of application, the concentration is preferably within a range from 0.1 to 30% by weight.

An ideal protective film material can be formed by dissolving a mixed resin containing a chain-like perfluoroalkylpolyether and a cyclic perfluoroalkylpolyether in perfluorotributylamine.

As the solvent for removing the protective film, the same fluorine-based solvents as those described above can be used.

There are no particular restrictions on the exposure wavelength used in the fifth and sixth aspects of the present invention, and exposure can be conducted using a KrF excimer laser, an ArF excimer laser, a F₂ laser, or other radiation such as EUV (extreme ultraviolet), VUW (vacuum ultraviolet), electron beam, soft X-ray, or X-ray radiation, although an ArF excimer laser is particularly preferred.

### EXAMPLES

As follows is a more detailed description of the present invention based on a series of examples, although the present invention is in no way restricted to these examples. Unless stated otherwise, blend quantities refer to % by weight values.

In the following examples, unless stated otherwise, the conditions for the simulated immersion lithography and the sensitivity measurements are as follows.

### (1) Conditions for Forming the Applied Resist Film

Substrate: 8 inch silicon wafer;

Resist application method: application using a spinner onto a substrate rotating at 2000 rpm;

Size of the applied resist film: diameter of 6 inches, concentric with the substrate, thickness 150 nm;

Prebake conditions: either 90 seconds at 110° C. (example 5) or 60 seconds at 95° C. (example 7);

Selective exposure conditions: exposure conducted using an ArF excimer laser (193 nm) (exposure apparatus NSR-S302B, manufactured by Nikon Corporation, NA (numerical aperture)=0.60, ⅔ annular illumination).

(2) Conditions for Contact between the Applied Resist Film and Solvent

Rotational speed of substrate: 500 rpm;

Solvent: water;

Solvent dripping rate: 1.0 L/minute

Solvent dripping time: 2 minutes or 5 minutes

Temperature of contact between solvent and resist: 23° C.

### (3) Conditions for Forming the Resist Pattern

Post exposure baking conditions: 90 seconds at 90° C. (example 5) or 60 seconds at 90° C. (example 7);

Alkali developing conditions: 60 seconds developing at 23° C. in a 2.38% by weight aqueous solution of tetramethylammonium hydroxide.

### Synthesis Example 1

20.0 g of hexafluoroisopropanol norbornene, 0.02 g of a 20% by weight isopropanol solution of chloroplatinic acid, and 30 g of tetrahydrofuran were poured into a 200 ml flask, and the mixture was heated to 70° C. with stirring. 9.2 g of tetrachlorosilane was then added dropwise to the solution over a period of 15 minutes. Following stirring for a further 5 hours, the mixture was distilled, yielding 15 g of hexafluoroisopropanol norbornyltrichlorosilane (a Si-containing monomer represented by the formula [29] shown below).

Next, 10 g of the thus obtained Si-containing monomer, 10 g of toluene, 10 g of methyl isobutyl ketone, 1.0 g of potassium hydroxide, and 5 g of water were poured into a 200 ml flask and stirred for one hour. Subsequently, the solution was diluted with methyl isobutyl ketone, and washed with 0.1 N hydrochloric acid until the pH value fell to no more than 8. The thus obtained solution was then filtered, and stirred for 12 hours at 200° C., thus yielding a polymer with a weight average molecular weight of 5,000. Following cooling, 30 g of tetrahydrofuran was added, and the resulting solution was stirred for one hour. This solution was then dripped into pure water, and the resulting precipitate was collected by filtration and vacuum dried, yielding 6.5 g of a white powder of a silsesquioxane polymer.

5 g of the thus obtained polymer, 10 g of tetrahydrofuran, and 3 g of sodium hydroxide were poured into a 100 ml flask, and 3 g of 2-methyl-2-adamantylbromoacetate were added gradually in a dropwise manner. After stirring for one hour, the solution was precipitated in 100 g of pure water, yielding a solid polymer. The resulting polymer was dissolved in methanol, and purified using an ion exchange resin. The resulting solution was then dripped into pure water, and the resulting precipitate was collected by filtration and vacuum dried, yielding 4 g of a white powder of the targeted silsesquioxane resin (polymer (x)). The structural formula of this resin is shown in [formula 30]. The polydispersity of the polymer (x) was 1.14. Furthermore, the relative proportions of the different structural units were [i]:[ii]=80:20 (molar ratio).

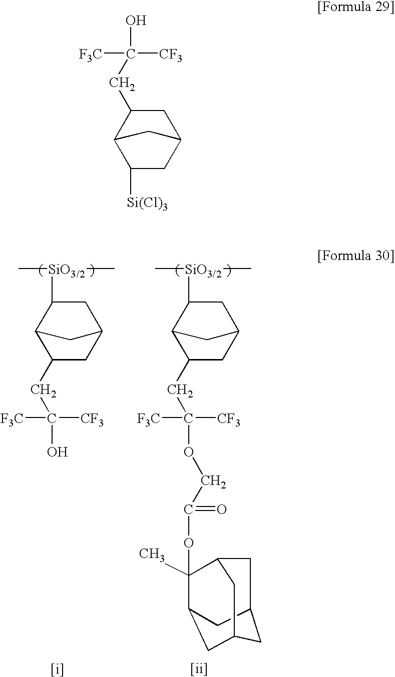

### Example 1

4 g of the polymer (x) obtained in the synthesis example 1 was dissolved in 75.9 g of ethyl lactate, and 0.12 g of triphenylsulfonium nonaflate and 0.008 g of tri-n-pentylamine were then added, thus forming a positive resist composition.

Next, using a solution generated by dissolving a novolak resin, produced by a condensation of m-cresol, p-cresol, and formalin in the presence of an oxalic acid catalyst, in an organic solvent as the lower resist material, this solution was applied to the surface of a silicon substrate using a spinner, and was then subjected to baking at 250° C. for 90 seconds, thus forming a lower resist layer with a film thickness of 300 nm.

The positive resist composition obtained above was then applied to the surface of the lower resist layer using a spinner, and was then prebaked and dried at 90° C. for 90 seconds, thus forming an upper resist layer of film thickness 100 nm, and completing formation of a resist laminate.

Subsequently, this upper resist layer was selectively irradiated with an ArF excimer laser (193 nm) through a binary mask pattern, using an ArF exposure apparatus NSR-S302 (manufactured by Nikon Corporation (NA (numerical aperture)=0.60, σ=0.75).

A PEB treatment was then performed at 90° C. for 90 seconds, and the resist layer was then developed for 60 seconds at 23° C. in a 2.38% by weight aqueous solution of tetramethylammonium hydroxide, thus yielding a 120 nm line and space (L&S) pattern (I) with favorable rectangularity.

This L&S pattern (I) was then subjected to oxygen plasma dry etching using a high vacuum RIE apparatus (manufactured by Tokyo Ohka Kogyo Co., Ltd.), thereby forming a L&S pattern (II) in the lower resist layer.

The resulting L&S pattern (II) had dimensions of 120 nm, and displayed excellent verticalness.

As a degas test, the above positive resist composition was applied to a silicon wafer with a film thickness of 2.0 μm, thereby forming a resist film. Subsequently, this resist film was subjected to a 1000 shot irradiation at 1000 mJ/cm², using light of wavelength 193 nm and an exposure apparatus equipped with a gas collection tube, and any generated gas was carried by a nitrogen stream to the collection tube. Analysis of the collected gas using GC-MS revealed no detection of organic silicon-based gases. Furthermore, organic non-silicon-based gases generated either during dissociation of the acid dissociable, dissolution inhibiting groups, or from the resist solvent, were detected at a level of approximately 150 ng.

Furthermore, the light permeability of the polymer (x) obtained in the synthesis example 1 was measured in the manner described below. The polymer (x) was dissolved in an organic solvent and then applied to the surface of a magnesium fluoride wafer in sufficient quantity to generate a dried film thickness of 0.1 μm. This applied film was dried to form a resin film, and the transparency (absorption coefficient) relative to light of wavelength 193 nm and light of wavelength 157 nm was measured using a vacuum ultraviolet spectrophotometer (manufactured by Jasco Corporation).

The results revealed a value of 3.003 abs/μm for 157 nm light, and a value of 0.0879 abs/μm for 193 nm light.

### Synthesis Example 2

With the exception of replacing the 2-methyl-2-adamantylbromoacetate from the synthesis example 1 with 2-ethyl-2-adamantylbromoacetate, the same method as the synthesis example 1 was used to produce a polymer (x1), in which the 2-methyl-2-adamantyl group of the polymer (x) from the synthesis example 1 had been replaced with a 2-ethyl-2-adamantyl group.

### Example 2

With the exception of replacing the polymer (x) obtained in the synthesis example 1 with the polymer (x1) obtained in the synthesis example 2, a positive resist composition was prepared in the same manner as the example 1. A resist laminate was then formed in the same manner as the example 1. When a resist pattern was then formed in the same manner as the example 1, a 120 nm line and space (L&S) pattern (1) of favorable rectangularity was obtained, and the same method was then used to form a 120 nm line and space (L&S) pattern (II) in the lower resist layer.

### Synthesis Example 3

With the exception of replacing the 20.0 g of hexafluoroisopropanol norbornene with 12 g of perfluoroisopentanol norbornene, the same method as the synthesis example 1 was used to produce a white, transparent polymer (x2) with the structural formula shown in [formula 31].

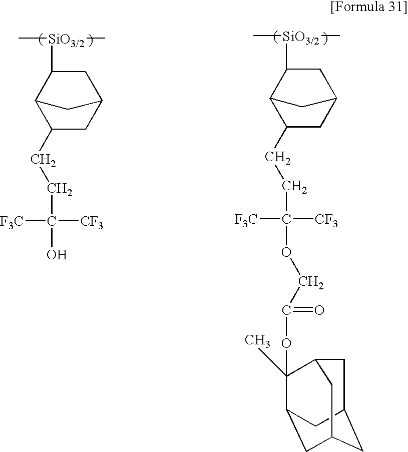

### Example 3

With the exception of replacing the polymer (x) obtained in the synthesis example 1 with the polymer (x2) obtained in the synthesis example 3, a positive resist composition was prepared in the same manner as the example 1. A resist laminate was then formed in the same manner as the example 1. When a resist pattern was then formed in the same manner as the example 1, a 120 nm line and space (L&S) pattern (I) of favorable rectangularity was obtained, and the same method was then used to form a 120 nm line and space (L&S) pattern (II) in the lower resist layer.

### Comparative Example 1

With the exception of replacing the polymer (x) from the example 1 with a polymer with the structural formula shown in [formula 32] (the polymer of the synthesis example 3 in which the acid dissociable, dissolution inhibiting group has been altered from a 2-methyl-2-adamantyl group to a 1-ethoxyethyl group), a resist pattern was formed in the same manner as the example 1.

As a result the upper resist layer could only be resolved down to 140 nm. Furthermore, when degas test measurements were conducted in the same manner as the example 1, organic non-silicon-based gases generated either during dissociation of the acid dissociable, dissolution inhibiting groups, or from the resist solvent, were detected at a level of approximately 600 mg.

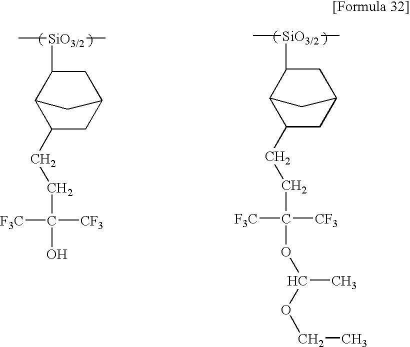

### Comparative Example 2

With the exception of replacing the positive resist composition of the example 1 with a resist composition formed from a propylene glycol monomethyl ether solution of poly-[p-hydroxybenzylsilsesquioxane-co-p-methoxybenzylsilsesquioxane-co-p(1-naphthoquinone-2-diazide-4-sulfonyloxy)-benzylsilsesquioxane], as disclosed in an example 4 of Japanese Unexamined Patent Application, First Publication No. Hei 06-202338 (or EP0599762), a resist pattern was formed in the same manner as the example 1.

As a result the L&S pattern (I) formed in the upper resist layer was a rounded shape with poor rectangularity, and the limiting resolution was 180 nm. Furthermore, the dimensions of the L&S pattern (I) and the L&S pattern (II) formed in the lower resist layer were different. The pattern could not be transferred to the lower resist.

### Example 4

A component (A), a component (B), an organic solvent component, and a quencher component described below were mixed together and dissolved, yielding a positive resist composition.

As the component (A), a mixed resin containing 85 parts by weight of the polymer (x) obtained in the synthesis example 1, and 15 parts by weight of a methacrylate-acrylate copolymer containing the three structural units shown in the [formula 33] was used. The proportions p, q, and r of each of the structural units in the copolymer were p=50 mol %, q=30 mol % and r=20 mol % respectively, and the weight average molecular weight was 10,000.

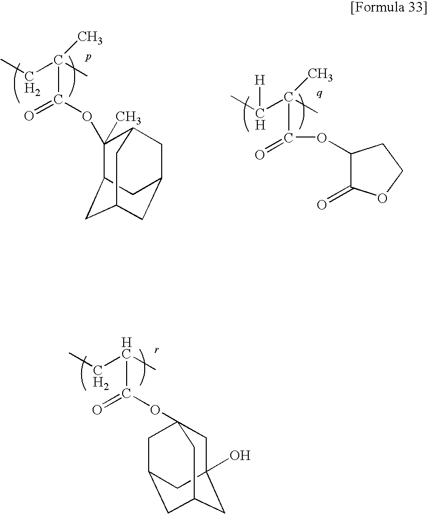

As the component (B), 3 parts by weight of triphenylsulfonium nonafluorobutanesulfonate was used.

As the organic solvent component, 1900 parts by weight of a mixed solvent of propylene glycol monomethyl ether acetate and ethyl lactate (weight ratio 6:4) was used.

As the quencher component, 0.25 parts by weight of triethanolamine was used.

Next, using the thus obtained positive resist composition, and using the same method as the example 1 with the exceptions of altering the prebake temperature to 100° C., and altering the film thickness of the upper resist layer to 150 nm, an upper resist layer was formed on top of a lower resist layer that had been formed in the same manner as the example 1, thus generating a resist laminate.

Resist pattern formation was then conducted in the same manner as the example 1, with the exceptions of altering the mask from a binary mask to a half tone mask, and leaving the post exposure baking temperature at 90° C., but adding an additional post bake of the developed resist pattern for 60 seconds at 100° C.

The resulting resist pattern with a 1:1 line and space pattern of 120 nm was inspected using a scanning electron microscope (SEM), revealing a pattern with favorable rectangularity. Furthermore, the sensitivity (Eth) was 28.61 mJ/cm². Furthermore, the exposure margin across which the 120 nm line pattern could be obtained within a variation of ±10% was a very favorable 10.05%. The depth of focus at which a 120 nm line and space pattern was obtained at a ratio of 1:1 was a satisfactory 0.6 μm. Furthermore, the limiting resolution was 110 nm.

### Example 5

### Immersion Lithography

With the exception of altering the quantity of triethanolamine to 0.38 parts by weight, a positive resist composition was prepared in the same manner as the example 4.

Next, using the thus obtained positive resist composition, and using the same method as the example 1 with the exceptions of altering the prebake temperature to 110° C., and altering the film thickness of the upper resist layer to 150 nm, an upper resist layer was formed on top of a lower resist layer that had been formed in the same manner as the example 1, thus generating a resist laminate.

The resist laminate was then selectively irradiated with an ArF excimer laser (193 nm) through a phase shift mask pattern, using an exposure apparatus NSR-S302B (manufactured by Nikon Corporation (NA (numerical aperture)=0.60, ⅔ annular illumination). Then, an immersion lithography treatment was conducted by rotating the silicon wafer including the exposed resist layer while pure water was dripped continuously onto the surface at 23° C. for a period of 5 minutes.

A PEB treatment was then performed at 90° C. for 90 seconds, and the resist layer was then developed for 60 seconds in an alkali developing solution at 23° C. As the alkali developing solution, a 2.38% by weight aqueous solution of tetramethylammonium hydroxide was used.

The resulting resist pattern with a 1:1 line and space pattern of 130 nm was inspected using a scanning electron microscope (SEM), and the sensitivity at that point (Eth) was also determined.

With the positive resist composition of this example, Eth was 17.0 mJ/cm². This value is X2. The resist pattern showed a favorable shape with no surface roughness.

On the other hand, when the positive resist composition of this example was used to form a resist pattern using a conventional exposure in air (normal exposure), without conducting the immersion lithography treatment described above, the resulting Eth value was 18.0 mJ/cm². This value is X1.

Determining the absolute value from the formula [(X2/X1)−1]×100 revealed a value of 5.56. When the ratio of the sensitivity of the immersion lithography treatment relative to the sensitivity for normal exposure was determined, the result was (17.0/18.0), or 0.94. Furthermore, the resist pattern was of a favorable shape with no visible surface roughness.

### Synthesis Example 4

20.0 g of hexafluoroisopropanol norbornene, 0.02 g of a 20% by weight isopropanol solution of chloroplatinic acid, and 30 g of tetrahydrofuran were poured into a 200 ml flask, and the mixture was heated to 70° C. with stirring. 9.2 g of tetrachlorosilane was then added dropwise to the solution over a period of 15 minutes. Following stirring for a further 5 hours, the mixture was distilled, yielding 15 g of hexafluoroisopropanol norbornyltrichlorosilane (a Si-containing monomer represented by the [formula 29]).

Next, 10 g of the thus obtained Si-containing monomer, 1.36 g of methyltrimethoxysilane (a Si-containing monomer represented by the chemical formula [34] shown below), 10 g of toluene, 10 g of methyl isobutyl ketone, 1.0 g of potassium hydroxide, and 5 g of water were poured into a 200 ml flask and stirred for one hour. Subsequently, the solution was diluted with methyl isobutyl ketone, and washed with 0.1 N hydrochloric acid until the pH value fell to no more than 8. The thus obtained solution was then filtered, and stirred for 12 hours at 200° C., thus yielding a polymer with a weight average molecular weight of 7,700. Following cooling, 30 g of tetrahydrofuran was added, and the resulting solution was stirred for one hour. This solution was then dripped into pure water, and the resulting precipitate was collected by filtration and vacuum dried, yielding 8 g of a white powder of a silsesquioxane polymer.

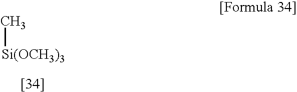

5 g of the thus obtained polymer, 10 g of tetrahydrofuran, and 3 g of sodium hydroxide were poured into a 100 ml flask, and 3 g of 2-methyl-2-adamantylbromoacetate were added gradually in a dropwise manner. After stirring for one hour, the solution was precipitated in 100 g of pure water, yielding a solid polymer. The resulting polymer was dissolved in methanol, and purified using an ion exchange resin. The resulting solution was then dripped into pure water, and the resulting precipitate was collected by filtration and vacuum dried, yielding 4 g of a white powder of the targeted silsesquioxane resin (polymer (x3)). The structural formula of this resin is shown in [formula 35]. The polydispersity of the polymer (x3) was 1.93. Furthermore, the relative proportions of the different structural units were [i]:[ii]:[iii]=60:10:30 (molar ratio).

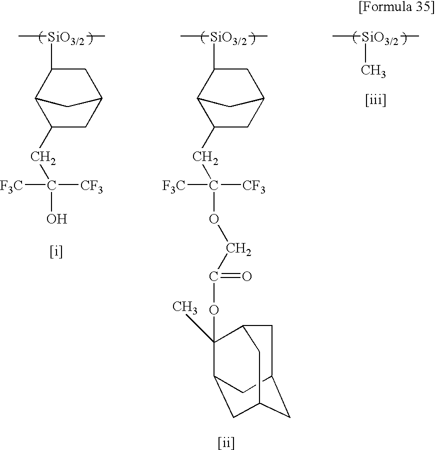

### Example 6

A component (A), a component (3), an organic solvent component, an amine component that acted as a quencher, and an organic carboxylic acid component that also acted as a quencher were mixed together and dissolved, yielding a positive resist composition.

As the component (A), a mixed resin containing 85 parts by weight of the polymer (x3) obtained in the synthesis example 4, and 15 parts by weight of a methacrylate-acrylate copolymer containing the three structural units shown in the [formula 36] was used. The proportions s, t, and u of each of the structural units in the copolymer were s=40 mol %, t=40 mol % and u 20 mol % respectively, and the weight average molecular weight was 11,000.

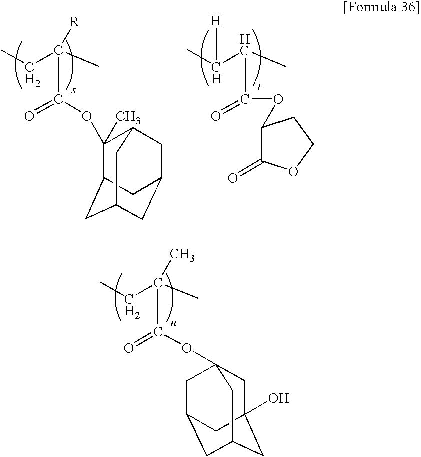

As the component (B), 2.4 parts by weight of triphenylsulfonium nonafluorobutanesulfonate was used.

As the organic solvent component, 1900 parts by weight of a mixed solvent of ethyl lactate and γ-butyrolactone (weight ratio 8:2) was used.

As the amine component that acted as a quencher, 0.27 parts by weight of triethanolamine was used.

As the organic carboxylic acid component that acted as a quencher, 0.26 parts by weight of salicylic acid was used.

Subsequently, an organic anti-reflective film composition AR-19 (manufactured by Shipley Co., Ltd.) was applied to the surface of a silicon wafer using a spinner, and was then baked and dried at 215° C. for 60 seconds on a hotplate, thereby forming an anti-reflective film with a film thickness of 82 nm. The positive resist composition described above was then applied to the top of this anti-reflective film using a spinner, and was prebaked and dried on a hotplate at 95° C. for 60 seconds, thus forming a resist layer with a film thickness of 150 nm on top of the anti-reflective film.

Next, this layer was selectively irradiated with an ArF excimer laser (193 nm) through a phase shift mask, using an exposure apparatus NSR-S302B (manufactured by Nikon Corporation (NA (numerical aperture)=0.60, ⅔ annular illumination). A PEB treatment was then performed at 90° C. for 60 seconds, and the resist layer was then developed for 60 seconds in an alkali developing solution at 23° C. As the alkali developing solution, a 2.38% by weight aqueous solution of tetramethylammonium hydroxide was used.

The resulting resist pattern with a 1:1 line and space pattern of 130 nm was inspected using a scanning electron microscope (SEM), revealing a pattern with favorable rectangularity. Furthermore, the sensitivity (Eth) was 24.0 mJ/cm². Furthermore, the exposure margin across which the 130 nm line pattern could be obtained within a variation of ±10% was a very favorable 13.31%. The depth of focus at which a 130 nm line and space pattern was obtained at a ratio of 1:1 was a satisfactory 0.6 μm. Furthermore, the limiting resolution was 110 nm.

### Example 7

### Immersion Lithography

Using the positive resist composition produced in the example 6, an immersion lithography treatment was conducted.

First, an organic anti-reflective film composition AR-19 (manufactured by Shipley Co., Ltd.) was applied to the surface of a silicon wafer using a spinner, and was then baked and dried at 215° C. for 60 seconds on a hotplate, thereby forming an anti-reflective film layer with a film thickness of 82 nm. The positive resist composition was then applied to the top of this anti-reflective film using a spinner, and was then prebaked and dried on a hotplate at 95° C. for 60 seconds, thus forming a resist layer with a film thickness of 150 nm on top of the anti-reflective film.

Next, this layer was selectively irradiated with an ArF excimer laser (193 nm) through a half tone phase shift mask, using an exposure apparatus NSR-S302B (manufactured by Nikon Corporation (NA (numerical aperture) 0.60, ⅔ annular illumination). Then, a simulated immersion lithography treatment was conducted by rotating the silicon wafer including the exposed resist layer at 2000 rpm for 5 seconds, and then at 500 rpm for 115 seconds, while pure water was dripped onto the surface for a period of 2 minutes at 23° C.

A PEB treatment was then performed at 90° C. for 60 seconds, and the resist layer was then developed for 60 seconds in an alkali developing solution at 23° C. As the alkali developing solution, a 2.38% by weight aqueous solution of tetramethylammonium hydroxide was used.

The resulting resist pattern with a 1:1 line and space pattern of 130 nm was inspected using a scanning electron microscope (SEM), and the sensitivity at that point (Eop) was also determined.

For the positive resist composition of this example, the Eop value was 25.0 mJ/cm². This value is X2. Furthermore, the resist pattern was of a favorable shape with no visible surface roughness or swelling.

On the other hand, when the positive resist composition of this example was used to form a resist pattern using a normal exposure lithography process in which the aforementioned simulated immersion lithography treatment was not performed, in other words, conducting the resist pattern formation using the same method as that described above but with the exception of not conducting the simulated immersion lithography treatment, the value of Eop was 24.0 mJ/cm². This value is X1.

Determining the absolute value from the formula [(X2/X1)−1]×100 revealed a value of 4.16. When the ratio of the sensitivity of the simulated immersion lithography treatment relative to the sensitivity for normal exposure was determined, the result was (25.0/24.0), or 1.04. Furthermore, the pattern profile was of a favorable shape with no visible surface roughness or swelling. Furthermore, the exposure margin across which the 130 nm line pattern could be obtained within a variation of +10% was a very favorable 12.97%. The limiting resolution was 110 nm

### Example 8

### Immersion Lithography

A component (A), a component (B), an organic solvent component, an amine component that acted as a quencher, and an organic carboxylic acid component that also acted as a quencher were mixed together and dissolved, yielding a positive resist composition.

As the component (A), a mixed resin containing 85 parts by weight of the polymer (x3) obtained in the synthesis example 4, and 15 parts by weight of a methacrylate-acrylate copolymer containing the three structural units shown in the [formula 37] was used. The proportions v, w, and x of each of the structural units in the copolymer were v=40 mol %, w=40 mol % and x 20 mol % respectively, and the weight average molecular weight was 10,000.

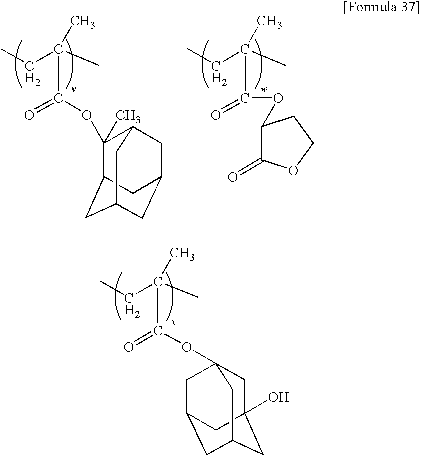

As the component (B), 2.4 parts by weight of triphenylsulfonium nonafluorobutanesulfonate was used.

As the organic solvent component, 1150 parts by weight of a mixed solvent of ethyl lactate and γ-butyrolactone (weight ratio 8:2) was used.

As the amine component that acted as a quencher, 0.27 parts by weight of triethanolamine was used.

As the organic carboxylic acid component that acted as a quencher, 0.26 parts by weight of salicylic acid was used.

Subsequently, an organic anti-reflective film composition AR-19 (manufactured by Shipley Co., Ltd.) was applied to the surface of a silicon wafer using a spinner, and was then baked and dried at 215° C. for 60 seconds on a hotplate, thereby forming an anti-reflective film with a film thickness of 82 nm. The positive resist composition described above was then applied to the top of this anti-reflective film using a spinner, and was prebaked and dried on a hotplate at 95° C. for 90 seconds, thus forming a resist layer with a film thickness of 150 nm on top of the anti-reflective film.

Next, a mixed resin containing Demnum S-10 (manufactured by Daikin Industries, Ltd.), and Cytop (manufactured by Asahi Glass Co., Ltd.) (mixture weight ratio=1:5) was dissolved in perfluorotributylamine to form a fluorine-based protective film material with a resin concentration of 2.5% by weight, and this material was applied to the surface of the above resist film using a spinner, and was then heated at 90° C. for 60 seconds, thus forming a protective film with a film thickness of 37 nm.

Then, as an evaluation test 2, immersion lithography was conducted using a test apparatus manufactured by Nikon Corporation, by carrying out a test using a prism, water, and the interference of two beams of 193 nm (a double beam interference test). The same method is disclosed in the aforementioned non-patent reference 2, and this method is widely known as a simple method of obtaining a L&S pattern at the laboratory level.

In the immersion lithography of this example 8, a water solvent layer was formed between the upper surface of the protective film and the lower surface of the prism as the immersion solvent.

The exposure dose was selected so as to allow stable formation of a L&S pattern. Next, a PEB treatment was conducted at 90° C. for 90 seconds, and the protective film was then removed using perfluoro(2-butyltetrahydrofuran). Subsequently, developing was conducted in the same manner as the example 1, yielding a 65 nm line and space pattern (1:1). The pattern shape showed a high level of rectangularity.

From the results of the examples 1 to 3 and the comparative examples 1 and 2 it is clear that in the two-layer resist method described above, by using a positive resist composition containing a silsesquioxane resin of the present invention, the degas phenomenon can be suppressed, and a resist pattern with dimensions of approximately 100 nm can be formed with a high aspect ratio and a favorable shape, even when a high energy light of no more than 200 nm or an electron beam is used as the exposure source. Furthermore, the positive resist composition displays a high level of transparency relative to high energy light of no more than 200 nm and electron beams, and provides excellent resolution.

Furthermore, from the results of the example 4 it is clear that by using a positive resist composition containing a mixed resin of a silsesquioxane resin of the present invention and a (meth)acrylate ester resin, a resist pattern with dimensions of approximately 100 nm can be formed which has a high aspect ratio and a favorable shape, and also exhibits an excellent exposure margin and depth of focus.

Furthermore, from the results of the example 6 it is clear that even when a positive resist composition containing a mixed resin of a silsesquioxane resin of the present invention and a (meth)acrylate ester resin is used as a single layer, a resist pattern with dimensions of approximately 100 nm can still be formed with a favorable shape, and excellent exposure margin and depth of focus.

In addition, from the immersion lithography results of the examples 5, 7, and 8 it is evident that a positive resist composition of the present invention is also ideal for immersion processes using a water solvent. In other words, a favorable resist pattern with no surface roughness can be formed, and the sensitivity ratio indicates that sensitivity is essentially the same as that for normal exposure, meaning the resist composition is resistant to any deleterious effects of the immersion solvent. If a resist is affected by the water solvent, then surface roughness appears within the resist pattern, and the sensitivity ratio varies by 10% or more.

### EFFECTS OF THE INVENTION

As described above, according to a silsesquioxane resin of the present invention, a positive resist composition containing the silsesquioxane resin, a resist laminate that uses the positive resist composition, and a method of forming a resist pattern using the resist laminate, the degas phenomenon can be suppressed, and a resist pattern with high levels of transparency and resolution can be formed. Furthermore, according to the present invention, a positive resist composition and a method of forming a resist pattern that are ideal for immersion lithography processes can be obtained.

### INDUSTRIAL APPLICABILITY

The present invention can be used in the formation of resist patterns, and is extremely useful industrially.

What is claimed is:

1. A positive resist composition used in a method of forming a resist pattern that comprises an immersion lithography step, wherein if a sensitivity when a 1:1 line and space resist pattern of 130 nm is formed by a normal exposure lithography process using a light source with a wavelength of 193 nm is termed X1, and a sensitivity when an identical 1:1 line and space resist pattern of 130 nm is formed by a simulated immersion lithography process, in which a step for bringing a solvent for said immersion lithography in contact with a resist film is inserted between a selective exposure step and a post exposure baking (PEB) step of a normal exposure lithography process, using a light source with a wavelength of 193 nm is termed X2, then said positive resist composition is a positive resist composition comprising a silsesquioxane resin as a resin component, for which an absolute value of [(X2/X1)−1]×100 is no more than 8.0.

2. A positive resist composition according to claim 1, which is used in a method of forming a resist pattern wherein during said immersion lithography step, a region between a resist layer formed from said positive resist composition, and a lens at a lowermost point of an exposure apparatus is filled with a solvent which has a larger refractive index than a refractive index of air.

3. A method of forming a resist pattern using a positive resist composition according to claim 1, comprising an immersion lithography step.

4. A method of forming a resist pattern according to claim 3, wherein during said immersion lithography step, following formation of a resist layer using a positive resist composition according to claim 1, a region between said resist layer and a lens at a lowermost point of an exposure apparatus is filled with a solvent which has a larger refractive index than a refractive index of air.
